(19) United States
(12) Patent Application Publication
(10) Pub. No.: US 2025/0273259 A1
(43) Pub. Date: Aug. 28, 2025

(54) SEMICONDUCTOR MEMORY DEVICE

(71) Applicant: Samsung Electronics Co., Ltd., Suwon-si (KR)

(72) Inventors: Junhee CHO, Suwon-si (KR); IN CHEOL NAM, Suwon-si (KR); SANG-YUN KIM, Suwon-Si (KR); SUN YOUNG KIM, Suwon-si (KR)

(21) Appl. No.: 18/927,193

(22) Filed: Oct. 25, 2024

(30) Foreign Application Priority Data
Feb. 27, 2024 (KR) 10-2024-0028319

(51) Int. Cl. G11C 11/4091; G11C 11/408; H01L 25/065; H01L 25/18; H10B 80/00

(52) U.S. Cl. CPC G11C 11/4091; G11C 11/4085; H01L 25/0657; H01L 25/18; H10B 80/00

(57) ABSTRACT

A semiconductor memory device includes a first semiconductor structure, and a second semiconductor structure. The first semiconductor structure and the second semiconductor structure are vertically stacked on each other. The first semiconductor structure includes a memory cell array including a plurality of memory cells. The second semiconductor structure includes a plurality of bitline sense amplifier sets configured to perform a data sensing operation on the plurality of memory cells based on a plurality of driving signal sets, and a plurality of monitoring circuit sets configured to monitor the plurality of driving signal sets to output a plurality of monitoring data.

### CROSS-REFERENCE TO RELATED APPLICATIONS

This application claims priority under 35 U.S.C. § 119 to Korean Patent Application No. 10-2024-0028319 filed on Feb. 27, 2024, in the Korean Intellectual Property Office, the disclosures of which is incorporated by reference herein in its entirety.

### BACKGROUND

Embodiments of the present disclosure described herein relate to a semiconductor device, and more particularly, relate to a semiconductor memory device.

A semiconductor memory device may be classified as a volatile memory device or a nonvolatile memory device. The volatile memory device may retain data stored therein while a power is supplied, and the nonvolatile memory device may retain data stored therein even during a time when a power is turned off. The volatile memory device provides a fast speed, and the nonvolatile memory device provides excellent safety and endurance.

To increase the storage capacity of the semiconductor memory device and to make the degree of integration of the semiconductor memory device higher, nowadays, there are being developed a cell over periphery (COP) structure and a periphery over cell (POC) structure in which memory cells are arranged three-dimensionally instead of two-dimensionally. In the COP structure, peripheral circuits are disposed under memory cells, and in the POC structure, peripheral circuits are disposed over memory cells.

### SUMMARY

Embodiments of the present disclosure provide a semiconductor memory device capable of optimizing elements capable of affecting the yield.

According to an aspect of the present disclosure, a semiconductor memory device includes a first semiconductor structure, and a second semiconductor structure. The first semiconductor structure and the second semiconductor structure are vertically stacked on each other. The first semiconductor structure includes a memory cell array including a plurality of memory cells. The second semiconductor structure includes a plurality of bitline sense amplifier sets configured to perform a data sensing operation on the plurality of memory cells based on a plurality of driving signal sets, and a plurality of monitoring circuit sets configured to monitor the plurality of driving signal sets to output a plurality of monitoring data.

According to an aspect of the present disclosure, a semiconductor memory device with a cell over periphery (COP) includes a first semiconductor structure, and a second semiconductor structure disposed under the first semiconductor structure. The first semiconductor structure includes a memory cell array including a plurality of memory cells. The second semiconductor structure includes a plurality of bitline sense amplifier sets disposed in a first area of the second semiconductor structure, and configured to perform a data sensing operation on the plurality of memory cells based on a plurality of driving signal sets, and a plurality of monitoring circuit sets disposed in a second area of the second semiconductor structure, and configured to monitor the plurality of driving signal sets to output a plurality of monitoring data.

According to an aspect of the present disclosure, a semiconductor memory device with a periphery over cell (POC) includes a first semiconductor structure, and a second semiconductor structure disposed over the first semiconductor structure. The first semiconductor structure includes a memory cell array including a plurality of memory cells. The second semiconductor structure includes a plurality of bitline sense amplifier sets configured to perform a data sensing operation on the plurality of memory cells based on a plurality of driving signal sets, and a plurality of monitoring circuit sets configured to monitor the plurality of driving signal sets to output a plurality of monitoring data.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a semiconductor memory device according to an embodiment of the present disclosure.

FIG. 2A is a diagram for describing a first semiconductor structure of FIG. 1.

FIG. 2B is a diagram for describing a second semiconductor structure of FIG. 1.

FIG. 3 is a block diagram illustrating a bitline sense amplifier set and a monitoring circuit set of FIG. 2B.

FIG. 4A is a circuit diagram illustrating a bitline sense amplifier of FIG. 3.

FIG. 4B is a timing diagram for describing an operation of a bitline sense amplifier of FIG. 4A.

FIG. 5 is a diagram for describing the influence of a location of a bitline sense amplifier on driving signals.

FIG. 6 is a block diagram illustrating an embodiment of a monitoring circuit set of FIG. 3.

FIG. 7 is a block diagram illustrating an embodiment of a monitoring circuit set of FIG. 3.

FIG. 8 is a diagram for describing an embodiment of the relation of arrangement of bitline sense amplifiers and monitoring circuits of FIG. 1.

FIG. 9 is a block diagram illustrating a semiconductor memory device according to an embodiment of the present disclosure.

FIG. 10 is a diagram for describing a second semiconductor structure of FIG. 9.

FIG. 11 is a block diagram illustrating an embodiment of a monitoring circuit set of FIG. 10.

FIG. 12 is a diagram for describing an embodiment of the relation of arrangement of a bitline sense amplifier set, a sub-wordline driver set, and a monitoring circuit set of FIG. 11.

FIG. 13 is a block diagram illustrating a semiconductor memory device according to an embodiment of the present disclosure.

FIG. 14 is a diagram for describing a second semiconductor structure of FIG. 13.

FIG. 15 is a block diagram illustrating an embodiment of a bitline sense amplifier set, a monitoring circuit set, a driving signal adjustment circuit set, and a driving signal control circuit set of FIG. 14.

FIG. 16 is a block diagram illustrating an embodiment of a driving signal adjustment circuit set of FIG. 15.

FIG. 17 is a diagram for describing an operation of a driving signal adjustment circuit set of FIG. 16.

FIG. 18 is a block diagram illustrating an embodiment of a driving signal adjustment circuit set of FIG. 15.

FIG. 19 is a diagram for describing an operation of a driving signal adjustment circuit set of FIG. 18.

FIG. 20 is a diagram for describing an embodiment of the relation of arrangement of a bitline sense amplifier set, a monitoring circuit set, and a driving signal adjustment circuit set of FIG. 15.

FIG. 21 is a block diagram illustrating a semiconductor memory device according to an embodiment of the present disclosure.

FIG. 22 is a block diagram illustrating a semiconductor memory device according to an embodiment of the present disclosure.

FIG. 23 is a flowchart illustrating an operating method of a semiconductor memory device according to an embodiment of the present disclosure.

FIG. 24 is a flowchart illustrating an operating method of a semiconductor memory device according to an embodiment of the present disclosure.

### DETAILED DESCRIPTION

Some aspects of the embodiments may affect the yield in the process of manufacturing the semiconductor memory device. Below, embodiments of the present disclosure will be described in detail and clearly to such an extent that one skilled in the art easily carries out the present disclosure.

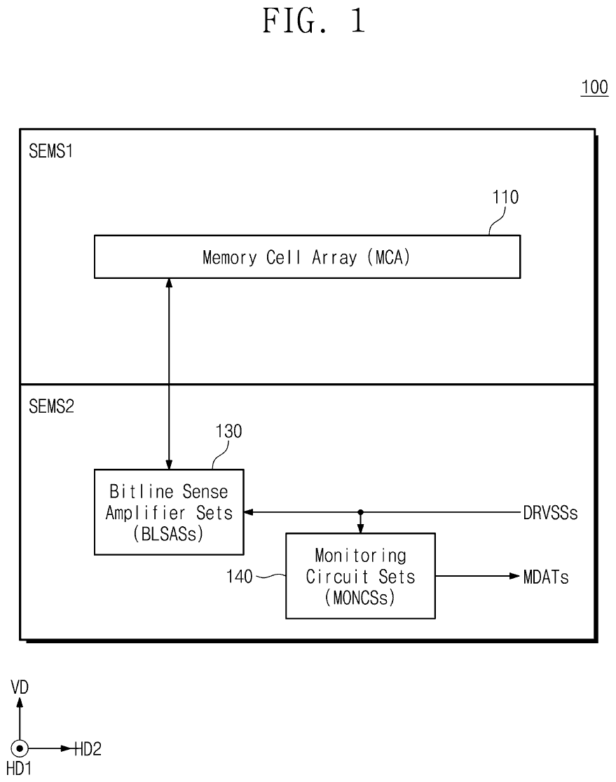

FIG. 1 is a block diagram illustrating a semiconductor memory device according to an embodiment of the present disclosure.

Referring to FIG. 1, a semiconductor memory device 100 may include a first semiconductor structure SEMS1 and a second semiconductor structure SEMS2. The first semiconductor structure SEMS1 may include a memory cell array (MCA) 110 including a plurality of memory cells, and the second semiconductor structure SEMS2 may include bitline sense amplifier sets (BLSASs) 130 and monitoring circuit sets (MONCSs) 140. The first semiconductor structure SEMS1 may include a first semiconductor substrate at which the MCA 110 may be formed, and the second semiconductor structure SEMS2 may include a second semiconductor substrate at which the BLSASs 130 and MONCSs 140 may be formed. The first and second semiconductor substrates may be silicon substrates or silicon-germanium substrates.

In an embodiment, the semiconductor memory device 100 may be a volatile memory device. For example, the semiconductor memory device 100 may include a dynamic random access memory (DRAM), a double data rate 4 (DDR4) synchronous DRAM (SDRAM), a low power DDR4 (LPDDR4) SDRAM, an LPDDR5 SDRAM, a graphics double data rate 5 (GDDR5) SDRAM, a GDDR6 SDRAM, a high bandwidth memory 2 (HBM2), an HBM2E, or an HBM3, but the present disclosure is not limited thereto.

In an embodiment, the semiconductor memory device 100 may have a cell over periphery (COP) structure in which peripheral circuits are disposed under the memory cell array 110, but the present disclosure is not limited thereto. In an embodiment, the semiconductor memory device 100 may have a periphery over cell (POC) structure in which the memory cell array 110 is disposed over peripheral circuits. For example, in FIG. 1, the second semiconductor structure SEMS2 is illustrated as being disposed under the first semiconductor structure SEMS1. However, unlike the example illustrated in FIG. 1, the first semiconductor structure SEMS1 may be disposed under the second semiconductor structure SEMS2.

In an embodiment, the plurality of memory cells may include vertical channel transistors (VCT) each of which includes a channel extending in a vertical direction. The present disclosure is not limited thereto. In an embodiment, the plurality of memory cells may include a horizontal channel transistor including a planar field effect transistor (FET), a fin field effect transistor (FinFET), a recessed channel array transistor (RCAT), a sphere-RCAT (S-RCAT), or a buried channel array transistor (BCAT).

The bitline sense amplifier sets 130 may perform a data sensing operation on the plurality of memory cells based on driving signal sets DRVSSs.

In an embodiment, each of the bitline sense amplifier sets 130 may include a plurality of bitline sense amplifiers, and each of the driving signal sets DRVSSs may include a plurality of driving signals for driving the plurality of bitline sense amplifiers, respectively.

For example, the plurality of memory cells may be electrically connected to bitlines and wordlines of the semiconductor memory device 100.

For example, one bitline sense amplifier may be electrically connected to two complementary bitlines of the semiconductor memory device 100 and may sense and amplify data stored in each of the plurality of memory cells based on a difference between voltages of the complementary bitlines during the data sensing operation of the semiconductor memory device 100.

For example, the plurality of driving signals may be provided to one bitline sense amplifier, and the bitline sense amplifier may perform a series of operations for performing the data sensing operation based on the driving signals provided thereto.

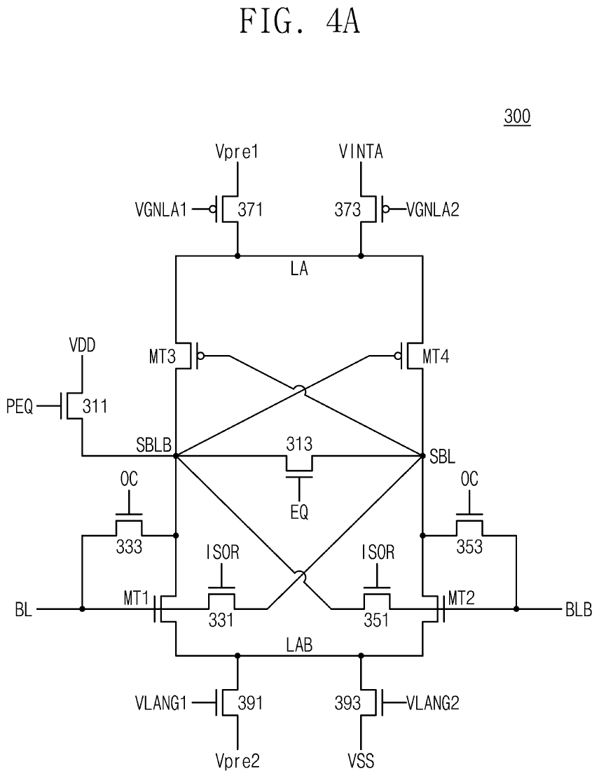

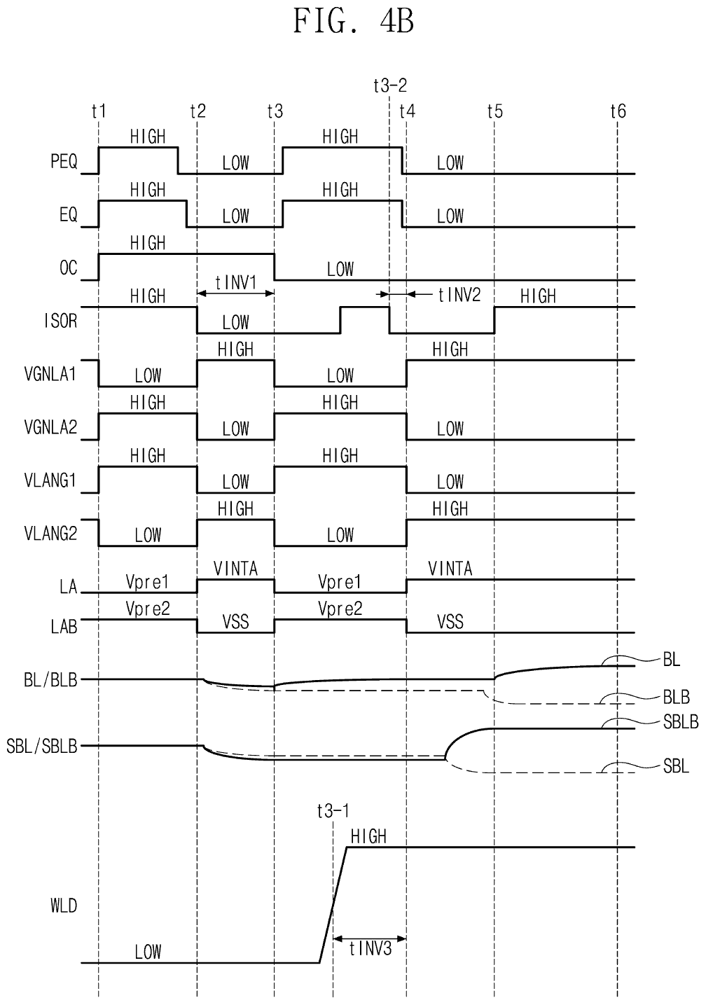

For example, the bitline sense amplifier (BLSA) may include a plurality of metal oxide semiconductor (MOS) transistors for performing the data sensing operation, and the driving signals provided to the bitline sense amplifier may be gate signals of the plurality of MOS transistors. The data sensing operation or a series of operations for the data sensing operation will be described with reference to FIGS. 4A and 4B.

The monitoring circuit sets 140 may monitor the driving signal sets DRVSSs to output a plurality of monitoring data MDATs.

In an embodiment, each of the monitoring circuit sets 140 may include a plurality of monitoring circuits, and one monitoring circuit may monitor some or all of driving signals provided to one bitline sense amplifier. For example, one monitoring circuit may monitor voltage levels of one or more driving signals provided to one bitline sense amplifier, transition time points of the voltage levels, or time intervals between the transition time points.

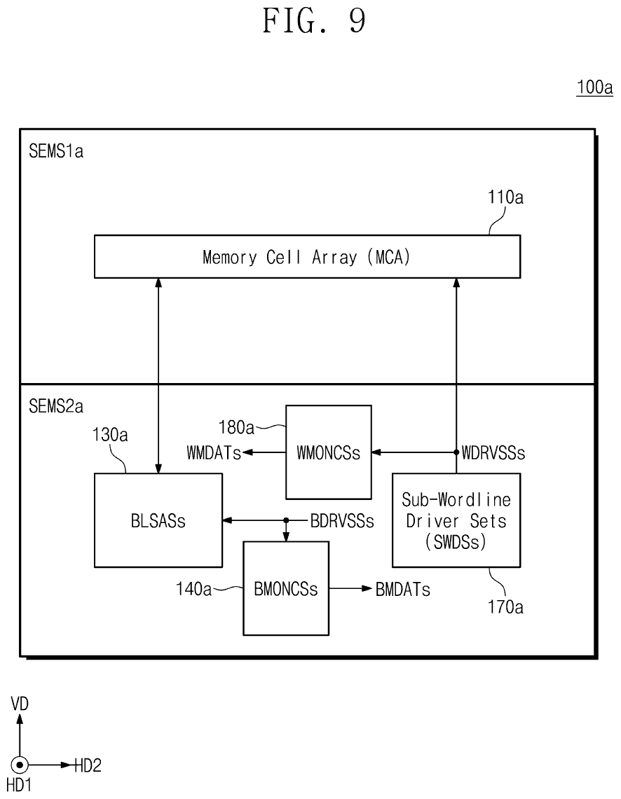

Even though illustrated in FIG. 1, the semiconductor memory device 100 according to an embodiment of the present disclosure may further include additional monitoring circuit sets which additionally monitor some or all of driving signals (also referred to as “wordline driving signals”) provided to a plurality of memory cells (or wordlines). The additional monitoring circuit sets will be described with reference to FIGS. 9, 10, 11, and 12.

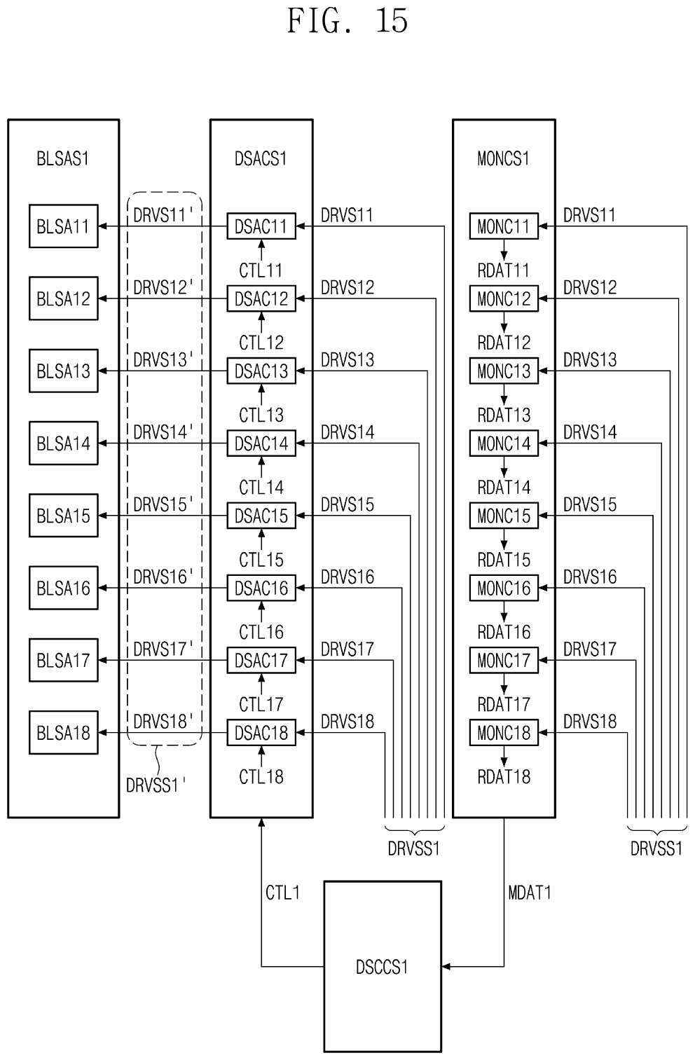

The semiconductor memory device 100 according to embodiments of the present disclosure may further include driving signal adjustment circuit sets which adjust driving timings or driving voltage levels of a plurality of driving signals provided to bitline sense amplifiers or a plurality of memory cells (or wordlines) based on the monitoring data MDATs and may further include driving signal control circuit sets which control the driving signal adjustment circuit sets. The driving signal adjustment circuit sets and the driving signal control circuit sets will be described with reference to FIGS. 15, 16, 17, 18, 19, and 20.

A vertical direction VD, a first horizontal direction HD1, and a second horizontal direction HD2 which are perpendicular to each other are illustrated in FIG. 1. In the following drawings, the vertical direction VD, the first horizontal direction HD1, and the second horizontal direction HD2 may be used in common. For example, the vertical direction VD may be an upward direction of the first semiconductor structure SEMS1 or the second semiconductor structure SEMS2. For example, the vertical direction VD may correspond to a direction in which the first and second semiconductor structures SEMS1 and SEMS2 are stacked on each other.

Through the above configuration, a semiconductor memory device according to embodiments of the present disclosure may monitor driving signals provided to a plurality of bitline sense amplifiers or a plurality of memory cells and may adjust driving timings or driving voltage levels of the driving signals based on a result of the monitoring. The monitoring may be directly associated with main features affecting the performance of bitline sense amplifiers or the like. Accordingly, the semiconductor memory device may monitor and adjust the driving timings or the driving voltage levels of the driving signals, thereby securing the performance of the semiconductor memory device and increasing the fabrication yield of the semiconductor memory device.

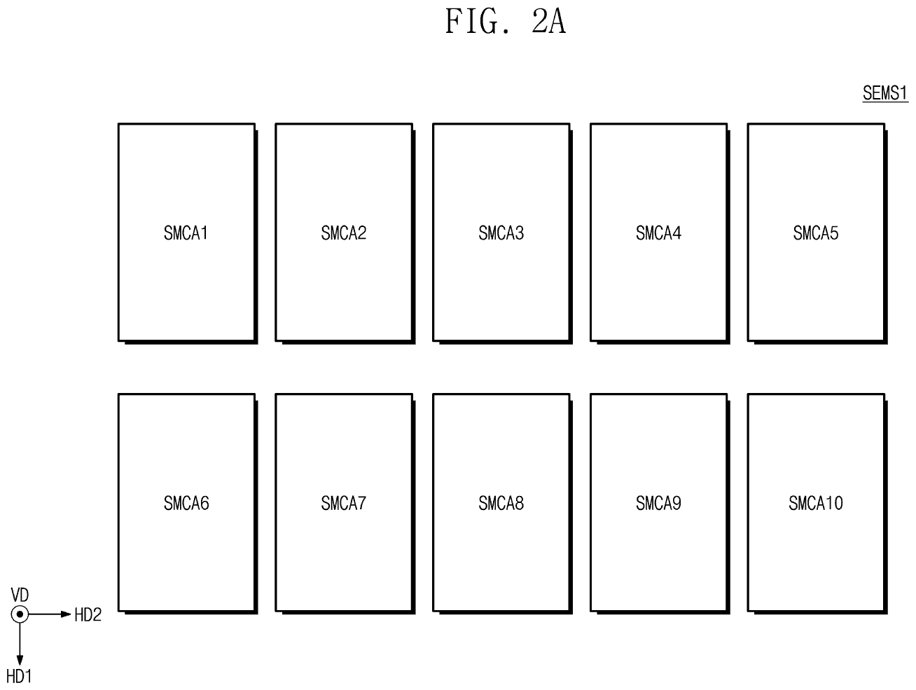

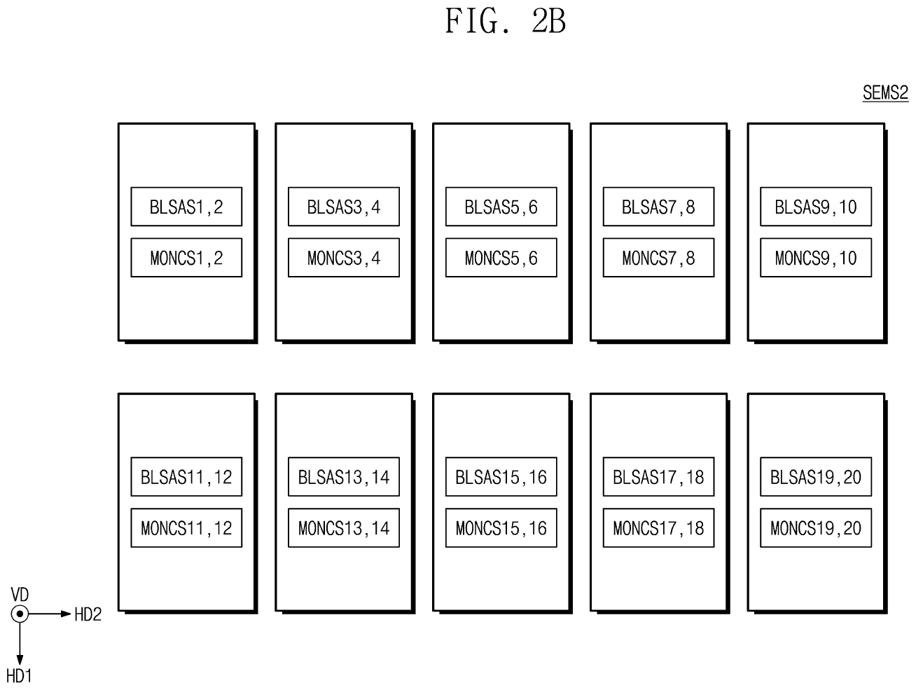

FIG. 2A is a diagram for describing a first semiconductor structure of FIG. 1.

Referring to FIG. 2A, the first semiconductor structure SEMS1 may include a plurality of sub memory cell arrays SMCA1, SMCA2, SMCA3, SMCA4, SMCA5, SMCA6, SMCA7, SMCA8 SMCA9 and SMCA10, each of which includes a plurality of memory cells connected to wordlines and bitlines. For example, the memory cell array 110 described with reference to FIG. 1 may include a plurality of memory cells, and the plurality of memory cells may be formed in the first semiconductor structure SEMS1 and may be arranged in sub memory cell arrays.

In an embodiment, the sub memory cell arrays SMCA1 to SMCA5 may be disposed at the first row of the first semiconductor structure SEMS1 in the second horizontal direction HD2, and the sub memory cell arrays SMCA6 to SMCA10 may be disposed at the second row of the first semiconductor structure SEMS1 in the second horizontal direction HD2.

FIG. 2B is a diagram for describing a second semiconductor structure of FIG. 1.

Referring to FIG. 2B, the second semiconductor structure SEMS2 may include bitline sense amplifier sets BLSAS1, BLSAS2, BLSAS3, BLSAS4, BLSAS5, BLSAS6, BLSAS7, BLSAS8, BLSAS9, BLSAS10, BLSAS11, BLSAS12, BLSAS13, BLSAS14, BLSAS15, BLSAS16, BLSAS17, BLSAS18, BLSAS19, and BLSAS20 and monitoring circuit sets MONCS1, MONCS2, MONCS3, MONCS4, MONCS5, MONCS6, MONCS7, MONCS8, MONCS9, MONCS10, MONCS11, MONCS12, MONCS13, MONCS14, MONCS15, MONCS16, MONCS17, MONCS18, MONCS19, and MONCS20.

Each of the bitline sense amplifier sets BLSAS1 to BLSAS20 may include a plurality of bitline sense amplifiers, and each of the monitoring circuit sets MONCS1 to MONCS20 may include a plurality of monitoring circuits.

In an embodiment, as illustrated in FIG. 2B, the bitline sense amplifier sets BLSAS1 to BLSAS20 and the monitoring circuit sets MONCS1 to MONCS20 may be disposed in corresponding areas which are under the plurality of sub memory cell arrays SMCA1 to SMCA10 described with reference to FIG. 2A and are within the second semiconductor structure SEMS2.

For example, the bitline sense amplifier sets BLSAS1 and BLSAS2 (marked by “BLSAS1, 2” in FIG. 2B) and the monitoring circuit sets MONCS1 and MONCS2 (marked by “MONCS1, 2” in FIG. 2B) may be disposed in corresponding areas which are under the sub memory cell array SMCA1 and are within the second semiconductor structure SEMS2. The bitline sense amplifier sets BLSAS3 and BLSAS4 (marked by “BLSAS3, 4” in FIG. 2B) and the monitoring circuit sets MONCS3 and MONCS4 (marked by “MONCS3, 4” in FIG. 2B) may be disposed in corresponding areas which are under the sub memory cell array SMCA2 and are within the second semiconductor structure SEMS2. The bitline sense amplifier sets BLSAS5 and BLSAS6 (marked by “BLSAS5, 6” in FIG. 2B) and the monitoring circuit sets MONCS5 and MONCS6 (marked by “MONCS5, 6” in FIG. 2B) may be disposed in corresponding areas which are under the sub memory cell array SMCA3 and are within the second semiconductor structure SEMS2.

For example, to be similar to the bitline sense amplifier sets BLSAS1 to BLSAS6 and the monitoring circuit sets MONCS1 to MONCS6, the bitline sense amplifier sets BLSAS7 to BLSAS20 and the monitoring circuit sets MONCS7 to MONCS20 may be disposed in corresponding areas which are under the sub memory cell arrays SMCA4 to SMCA10 and are within the second semiconductor structure SEMS2.

The plurality of sub memory cell arrays SMCA1 to SMCA10 of FIGS. 2A and 2B may be in the shape of a matrix with two rows and five columns, but this is only an example. Sub memory cell arrays may be disposed within the first semiconductor structure SEMS1 at less or more rows and less or more columns, and bitline sense amplifier sets or monitoring circuit sets may be disposed within the second semiconductor structure SEMS2 to correspond to the sub memory cell arrays, respectively.

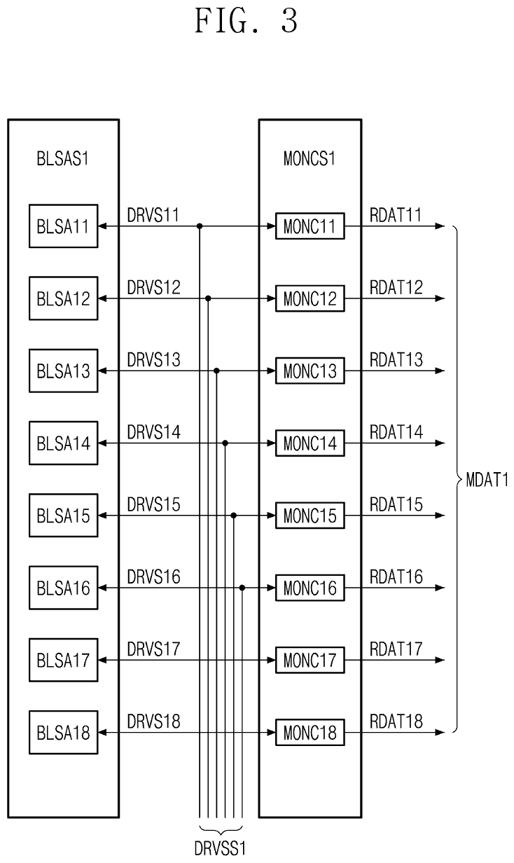

FIG. 3 is a block diagram illustrating a bitline sense amplifier set and a monitoring circuit set of FIG. 2B.

As described with reference to FIGS. 2A and 2B, a bitline sense amplifier set BLSAS1 and a monitoring circuit set MONCS1 may be disposed in areas which are under the sub memory cell array SMCA1 and are within the second semiconductor structure SEMS2 together with a bitline sense amplifier set BLSAS2 and a monitoring circuit set MONCS2. For convenience of description, the bitline sense amplifier set BLSAS1 and the monitoring circuit set MONCS1 are only illustrated in FIG. 3.

Referring to FIG. 3, the bitline sense amplifier set BLSAS1 may include bitline sense amplifiers BLSA11, BLSA12, BLSA13, BLSA14, BLSA15, BLSA16, BLSA17, and BLSA18, and the monitoring circuit set MONCS1 may include monitoring circuits MONC11, MONC12, MONC13, MONC14, MONC15, MONC16, MONC17, and MONC18.

The bitline sense amplifier set BLSAS1 may perform the data sensing operation on a plurality of memory cells included in the sub memory cell array SMCA1, based on a driving signal set DRVSS1. The monitoring circuit set MONCS1 may monitor the driving signal set DRVSS1 to output monitoring data MDAT1.

In an embodiment, the driving signal set DRVSS1 may include driving signals DRVS11, DRVS12, DRVS13, DRVS14, DRVS15, DRVS16, DRVS17, and DRVS18 respectively provided to the bitline sense amplifiers BLSA11 to BLSA18 and respectively provided to the monitoring circuits MONC11 to MONC18. As will be described with reference to FIGS. 4A and 4B, each of the driving signals DRVS11 to DRVS18 may represent a plurality of driving signals which are provided to one bitline sense amplifier. For example, each of the driving signals DRVS11 to DRVS18 may include a plurality of driving signals.

In an embodiment, the monitoring circuit MONC11 may monitor one or more of the driving signals DRVS11 provided to the bitline sense amplifier BLSA11 and may output result data RDAT11; the monitoring circuit MONC12 may monitor one or more of the driving signals DRVS12 provided to the bitline sense amplifier BLSA12 and may output result data RDAT12; the monitoring circuit MONC13 may monitor one or more of the driving signals DRVS13 provided to the bitline sense amplifier BLSA13 and may output result data RDAT13. The monitoring circuits MONC14 to MONC18 may also perform operations similar to the operations of the monitoring circuits MONC11 to MONC13 and may output result data RDAT14 to RDAT18. The result data RDAT11 to RDAT18 output from the monitoring circuits MONC11 to MONC18 may constitute one monitoring data MDAT1.

FIG. 4A is a circuit diagram illustrating a bitline sense amplifier of FIG. 3, and FIG. 4B is a timing diagram for describing an operation of a bitline sense amplifier of FIG. 4A.

In FIG. 4A, a bitline sense amplifier 300 may be one of the bitline sense amplifiers BLSA11 to BLSA18 illustrated in FIG. 3.

Referring to FIG. 4A, the bitline sense amplifier 300 may include n-type metal oxide semiconductor (NMOS) transistors MT1, MT2, 311, 313, 331, 333, 351, 353, 391, and 393 and p-type metal oxide semiconductor (PMOS) transistors MT3, MT4, 371, and 373.

In an embodiment, the bitline sense amplifier 300 may include an amplification unit, a first isolation/offset compensation control circuit, a second isolation/offset compensation control circuit, a first power supply circuit, and a second power supply circuit. For example, the amplification unit may include the MOS transistors MT1, MT2, 311, and 313. The first isolation/offset compensation control circuit may include the MOS transistors 331 and 333. The second isolation/offset compensation control circuit may include the MOS transistors 351 and 353. The first power supply circuit may include the MOS transistors 371 and 373. The second power supply circuit may include the MOS transistors 391 and 393.

For example, the MOS transistor MT1 may include a gate terminal connected to a bitline BL connected to a target memory cell targeted for the data sensing operation, and the MOS transistor MT2 may include a gate terminal connected to a complementary bitline BLB connected to a non-target memory cell not targeted for the data sensing operation. The MOS transistor MT1 may be connected between a second sensing node SBLB and a power supply node LAB, and the NMOS transistor MT2 may be connected between a first sensing node SBL and the power supply node LAB. The first sensing node SBL and the second sensing node SBLB may be internal nodes of the bitline sense amplifier 300.

For example, the MOS transistor 331 may be connected between the bitline BL and the first sensing node SBL, and the MOS transistor 333 may be connected between the bitline BL and the second sensing node SBLB.

For example, the MOS transistor 351 may be connected between the complementary bitline BLB and the second sensing node SBLB, and the MOS transistor 353 may be connected between the complementary bitline BLB and the first sensing node SBL.

For example, the MOS transistor 311 may be connected between a power node VDD and the second sensing node SBLB, and the MOS transistor 313 may be connected between the first sensing node SBL and the second sensing node SBLB.

For example, the MOS transistor MT3 may be connected between a power supply node LA and the second sensing node SBLB, and the MOS transistor MT4 may be connected between the power supply node LA and the first sensing node SBL.

For example, the MOS transistor 371 may be connected between a power node Vpre1 and the power supply node LA, and the MOS transistor 373 may be connected between a power node VINTA and the power supply node LA.

For example, the MOS transistor 391 may be connected between a power node Vpre2 and the power supply node LAB, and the MOS transistor 393 may be connected between a power node VSS and the power supply node LAB.

For example, the MOS transistor 311 may be referred to as a “first equalization transistor”, and the MOS transistor 313 may be referred to as a “second equalization transistor”. The MOS transistor 331 may be referred to as a “first isolation transistor”, and the MOS transistor 351 may be referred to as a “second isolation transistor”. The MOS transistor 333 may be referred to as a “first offset compensation transistor”, and the MOS transistor 353 may be referred to as a “second offset compensation transistor”. The MOS transistor 371 may be referred to as a “first power supply transistor”, and the MOS transistor 373 may be referred to as a “second power supply transistor”. The MOS transistor 391 may be referred to as a “third power supply transistor”, and the MOS transistor 393 may be referred to as a “fourth power supply transistor”.

In an embodiment, the bitline sense amplifier 300 may perform the data sensing operation on the target memory cell based on a plurality of driving signals. For example, the plurality of driving signals may be gate signals of the MOS transistors 311, 313, 331, 333, 351, 353, 371, 373, 391, and 393. For example, the plurality of driving signals may include a first equalization signal PEQ, a second equalization signal EQ, an isolation release signal ISOR, an offset compensation signal OC, and power supply control signals VGNLA1, VGNLA2, VLANG1, and VLANG2. The first equalization signal PEQ may be the gate signal of the first equalization transistor, and the second equalization signal EQ may be the gate signal of the second equalization transistor. The isolation release signal ISOR may be the gate signal of each of the first isolation transistor and the second isolation transistor, and the offset compensation signal OC may be the gate signal of each of the first offset compensation transistor and the second offset compensation transistor. The power supply control signal VGNLA1 (i.e., a first power supply control signal) may be the gate signal of the first power supply transistor, the power supply control signal VGNLA2 may be the gate signal of the second power supply transistor, the power supply control signal VLANG1 may be the gate signal of the third power supply transistor, and the power supply control signal VLANG2 may be the gate signal of the fourth power supply transistor.

In FIG. 4B, as time points t1, t2, t3, t3-1, t3-2, t4, t5, and t6 pass, the bitline sense amplifier 300 may perform the data sensing operation.

Referring to FIG. 4B, the data sensing operation may include a series of operations including a “precharge operation”, an “offset compensation operation”, a “charge sharing operation”, a “pre-sensing operation”, and a “restoring operation”. The precharge operation may be performed in the time interval from t1 to t2, and the offset compensation operation may be performed in the time interval from t2 to t3. The charge sharing operation may be performed in the time interval from t3 to t4, and the pre-sensing operation may be performed in the time interval from t4 to t5. The restoring operation may be performed during a time period from time points t5 to t6.

In an embodiment, as illustrated in FIG. 4B, the first equalization signal PEQ, the second equalization signal EQ, the offset compensation signal OC, the isolation release signal ISOR, and the power supply control signals VGNLA1, VGNLA2, VLANG1, and VLANG2 may be applied to the bitline sense amplifier 300 depending on the configuration described with reference to FIG. 4A such that the data sensing operation is performed.

For example, in the precharge operation, the first equalization signal PEQ and the second equalization signal EQ may maintain a high level and may then transition to a low level. Each of the offset compensation signal OC, the isolation release signal ISOR, and the power supply control signals VGNLA1, VGNLA2, VLANG1, and VLANG2 may maintain one of the high level and the low level.

For example, in the offset compensation operation, each of the first equalization signal PEQ, the second equalization signal EQ, the offset compensation signal OC, the isolation release signal ISOR, and the power supply control signals VGNLA1, VGNLA2, VLANG1, and VLANG2 may maintain one of the high level and the low level.

For example, in the charge sharing operation, each of the first equalization signal PEQ, the second equalization signal EQ, and the isolation release signal ISOR may transition from the low level to the high level and may then transition from the high level to the low level. Each of the offset compensation signal OC and the power supply control signals VGNLA1, VGNLA2, VLANG1, and VLANG2 may maintain one of the low level and the high level.

For example, in the pre-sensing operation, each of the first equalization signal PEQ, the second equalization signal EQ, the offset compensation signal OC, the isolation release signal ISOR, and the power supply control signals VGNLA1, VGNLA2, VLANG1, and VLANG2 may maintain one of the high level and the low level. Starting of the pre-sensing operation may include transitioning of the power supply control signal VGNLA1 (i.e., a first power supply control signal) from a low level to a high level, transitioning of the power supply control signal VGNLA2 from a high level to a low level, transitioning of the power supply control signal VLANG1 from a high level to a low level, and transitioning of the power supply control signal VLANG2 from a low level to a high level.

For example, in the restoring operation, each of the first equalization signal PEQ, the second equalization signal EQ, the offset compensation signal OC, the isolation release signal ISOR, and the power supply control signals VGNLA1, VGNLA2, VLANG1, and VLANG2 may maintain one of the high level and the low level.

Through the precharge operation, the offset compensation operation, the charge sharing operation, the pre-sensing operation, and the restoring operation, the voltage levels of the bitline BL, the complementary bitline BLB, the first sensing node SBL, and the second sensing node SBLB may change as illustrated in FIG. 4B, but this is only an example. In FIG. 4B, data corresponding a logical value of “1” may be stored in the target memory cell.

While the data sensing operation is performed, one or more time intervals (e.g., tINV1 and tINV2) may affect the performance of the bitline sense amplifier 300.

For example, the time interval tINV1 may indicate the entire time interval (e.g., from t2 to t3) in which the offset compensation operation is performed. To make the performance of offset compensation higher in different bitline sense amplifiers, there may be a need to maintain the time interval tINV1 to be substantially identical to that in each of different bitline sense amplifiers.

For example, the time interval tINV2 may indicate a portion of the time interval in which the charge sharing operation is performed. In the time interval where the charge sharing operation is performed (i.e., in a charge sharing time interval), the time interval tINV2 may be from a point in time (e.g., t3-2) when the isolation release signal ISOR transitions from the high level to the low level to a point in time (e.g., t4) when the time interval where the pre-sensing operation is performed starts. There may be a need to maintain the time interval tINV2 to be substantially identical to that in each of different bitline sense amplifiers such that offset information and the like according to the offset compensation operation is more accurately applied to the first sensing node SBL or the second sensing node SBLB.

One or more of the first equalization signal PEQ, the second equalization signal EQ, the offset compensation signal OC, the isolation release signal ISOR, and the power supply control signals VGNLA1, VGNLA2, VLANG1, and VLANG2 may correspond to one or more driving signals which are described with reference to FIG. 1 and are targeted for the monitoring. The time intervals tINV1 and tINV2 may correspond to time intervals between transition time points of the voltage levels of the driving signals.

A time interval (e.g., tINV3) associated with the voltage level of a driving signal WLD to be provided to one wordline may also be targeted for the monitoring. In the time interval where the charge sharing operation is performed, the time interval tINV3 may be from a point in point (e.g., t3-1) when the voltage level of the driving signal WLD transitions to the low level to the high level to a point in time (e.g., t4) when the time interval where the pre-sensing operation is performed starts. There may be a need to maintain the time interval tINV3 to be substantially identical between components associated with different target memory cells such that a development time interval in which the voltage levels of the bitline BL and the complementary bitline BLB change is identically maintained in each memory cell in the process of performing the charge sharing operation.

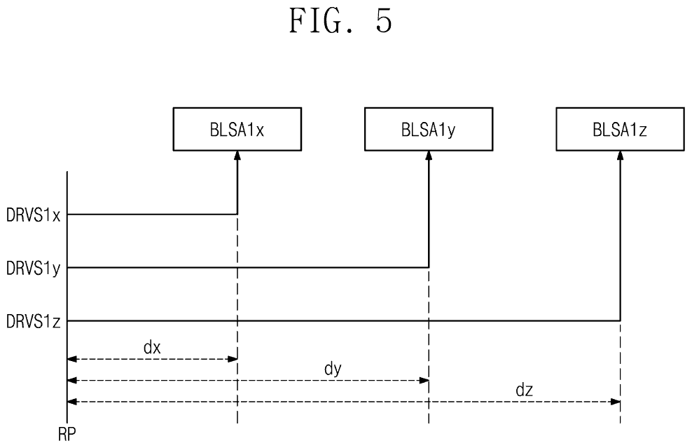

FIG. 5 is a diagram for describing the influence of a location of a bitline sense amplifier on driving signals.

Referring to FIG. 5, bitline sense amplifiers BLSA1x, BLSA1y, and BLSA1z are illustrated, and each of the bitline sense amplifiers BLSA1x, BLSA1y, and BLSA1z may be one of the bitline sense amplifiers BLSA11 to BLSA18 described with reference to FIG. 3. Driving signals DRVS1x, DRVS1y, and DRVS1z may be respectively provided to the bitline sense amplifiers BLSA1x, BLSA1y, and BLSA1z.

The driving signals DRVS1x, DRVS1y, and DRVS1z may be provided to the bitline sense amplifiers BLSA1x, BLSA1y, and BLSA1z from a circuit which is implemented at a reference position RP. For example, each of the driving signals DRVS1x, DRVS1y, and DRVS1z may be provided from a row decoder of a semiconductor memory device which is positioned at the reference position RP.

Distances from the reference position RP to the bitline sense amplifiers BLSA1x, BLSA1y, and BLSA1z may be different from each other. For example, as illustrated in FIG. 5, the distance from the reference position RP to the bitline sense amplifier BLSA1x may be dx, the distance from the reference position RP to the bitline sense amplifier BLSA1y may be dy greater than dx, and the distance from the reference position RP to the bitline sense amplifier BLSA1z may be dz greater than dy. Depending on a distance from the reference position RP to each bitline sense amplifier, a time taken for the driving signals DRVS1z to reach the bitline sense amplifier BLSA1z may be longer than a time taken for the driving signals DRVS1y to reach the bitline sense amplifier BLSA1y, and the time taken for the driving signals DRVS1y to reach the bitline sense amplifier BLSA1y may be longer than a time taken for the driving signals DRVS1x to reach the bitline sense amplifier BLSA1x.

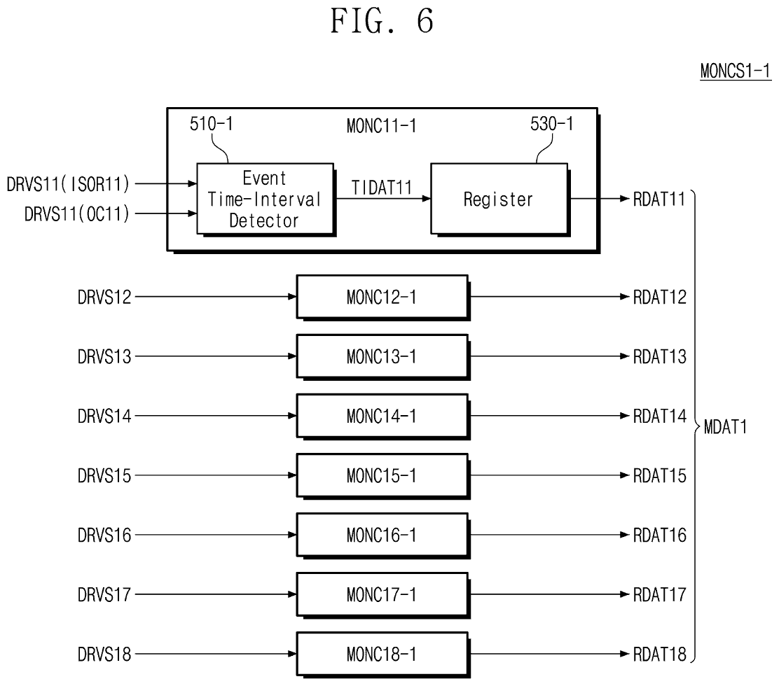

FIG. 6 is a block diagram illustrating an embodiment of a monitoring circuit set of FIG. 3.

Referring to FIG. 6, a monitoring circuit set MONCS1-1 may correspond to the monitoring circuit set MONCS1 of FIG. 3. The monitoring circuit set MONCS1-1 may include monitoring circuits MONC11-1, MONC12-1, MONC13-1, MONC14-1, MONC15-1, MONC16-1, MONC17-1, and MONC18-1. Each of the monitoring circuits MONC11-1 to MONC18-1 may monitor driving signals which are provided to one bitline sense amplifier. For example, one monitoring circuit (e.g., MONC11-1) may monitor one or more of driving signals (e.g., DRVS11) which are provided to one bitline sense amplifier.

The monitoring circuit MONC11-1 may include an event time-interval detector 510-1 and a register 530-1.

The event time-interval detector 510-1 may monitor a time interval between a transition time point of a voltage level of one (hereinafter referred to as a “first driving signal”) of the driving signals DRVS11 and a transition time point of a voltage level of another (hereinafter referred to as a “second driving signal”) thereof and may output time-interval data TIDAT11. In an embodiment, a transition time point of a signal refers to the moment when the signal changes from one state (e.g., a low level) to another (e.g., a high level). For example, the transition time point may correspond to the time at which the signal is at the midpoint between the low level and the high level.

In an embodiment, the event time-interval detector 510-1 may monitor a time interval between a time point when the voltage level of the first driving signal transitions from a first logic level to a second logic level and a time point when the voltage level of the second driving signal transitions from the first logic level to the second logic level.

For example, the first driving signal may be an isolation release signal ISOR11 among the driving signals DRVS11, the second driving signal may be an offset compensation signal OC11 among the driving signals DRVS11, and the event time-interval detector 510-1 may monitor the time interval tINV1 described with reference to FIG. 4B in association with the driving signals DRVS11. However, this is only an example. In an embodiment, the monitoring circuit MONC11-1 may monitor the time interval tINV2 described with reference to FIG. 4B and may also monitor various time intervals not provided in FIG. 4B as an example. In an embodiment, the event time-interval detector 510-1 may include a time interval counter which measures the time interval between the trigger points (e.g., transition time points) of the two input signals and output the result. For example, at a transition time point of the isolation release signal ISOR11 when a high level thereof changes to a low level thereof, the time interval counter may start, at a transition time point of the offset compensation signal OC11 when a high level thereof changes to a low level thereof, the time interval counter may stop.

The register 530-1 may store the time-interval data TIDAT11 and may output the result data RDAT11. In an embodiment, the time-interval data TIDAT11 may represent the time interval between a time point when the voltage level of the first driving signal transitions from a first level to a second level and a time point when the voltage level of the second driving signal transitions from the first level to the second level.

A configuration and an operation of each of the monitoring circuits MONC12-1 to MONC18-1 may be the same as or similar to the configuration and the operation of the monitoring circuit MONC11-1. Accordingly, the monitoring circuits MONC12-1 to MONC18-1 may monitor the driving signals DRVS12 to DRVS18 and may respectively output the result data RDAT12 to RDAT18.

The result data RDAT11 to RDAT18 may constitute the monitoring data MDAT1.

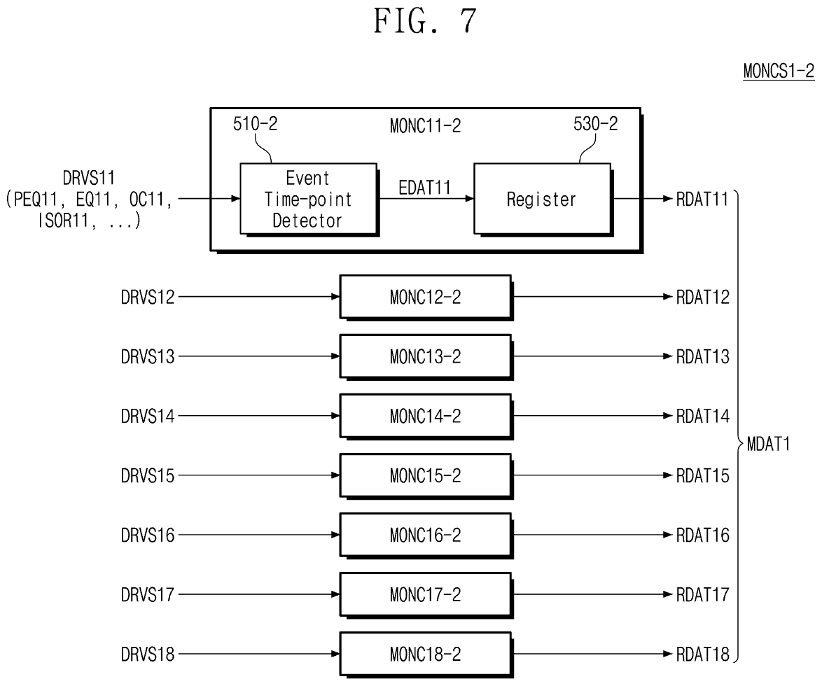

FIG. 7 is a block diagram illustrating an embodiment of a monitoring circuit set of FIG. 3.

Referring to FIG. 7, a monitoring circuit set MONCS1-2 may correspond to the monitoring circuit set MONCS1 of FIG. 3. The monitoring circuit set MONCS1-2 may include monitoring circuits MONC11-2, MONC12-2, MONC13-2, MONC14-2, MONC15-2, MONC16-2, MONC17-2, and MONC18-2. Each of the monitoring circuits MONC11-2 to MONC18-2 may monitor driving signals which are provided to one bitline sense amplifier. For example, one monitoring circuit (e.g., MONC11-2) may monitor one or more of driving signals (e.g., DRVS11) which are provided to one bitline sense amplifier.

The monitoring circuit MONC11-2 may include an event time-point detector 510-2 and a register 530-2.

The event time-point detector 510-2 may monitor a time point of each of voltage levels of one or more of the driving signals DRVS11 and may output event data EDAT11.

In an embodiment, the event time-point detector 510-2 may monitor a time point at which the voltage level of each of the one or more driving signals transitions from the first logic level to the second logic level.

For example, the one or more driving signals may include a first equalization signal PEQ11, a second equalization signal EQ11, an offset compensation signal OC11, and an isolation release signal ISOR11, and the event time-point detector 510-2 may monitor a transition time point of the voltage level of each of the one or more driving signals. However, this is only an example. In another embodiment, the event time-point detector 510-2 may also monitor a transition time point of the voltage level of each of the power supply control signals VGNLA1, VGNLA2, VLANG1, and VLANG2 among the driving signals described with reference to FIG. 4B. In an embodiment, the event time-point detector 510-2 may include a comparator which may detect when a signal crosses a certain threshold voltage, and which may detect the rising or falling edges of a signal. In an embodiment, the event time-point detector 510-2 may include an edge detector using a combination of logic gates such as XOR gates to detect edges of a signal. For example, by comparing the current and previous states of a signal, the edge detector may determine when a transition occurs.

The register 530-2 may store the event data EDAT11 and may output the result data RDAT11.

A configuration and an operation of each of the monitoring circuits MONC12-2 to MONC18-2 may be the same as or similar to the configuration and the operation of the monitoring circuit MONC11-2. Accordingly, the monitoring circuits MONC12-2 to MONC18-2 may monitor the driving signals DRVS12 to DRVS18 and may respectively output the result data RDAT12 to RDAT18.

The result data RDAT11 to RDAT18 may constitute the monitoring data MDAT1.

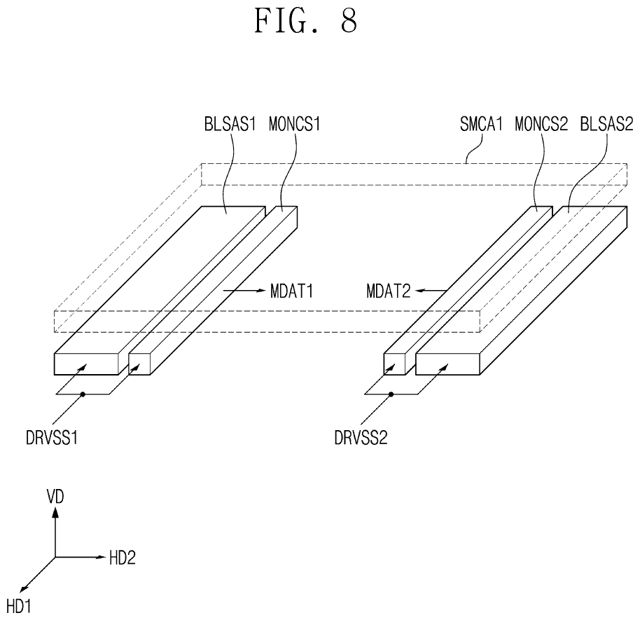

FIG. 8 is a diagram for describing an embodiment of the relation of arrangement of bitline sense amplifiers and monitoring circuits of FIG. 1.

The bitline sense amplifier sets BLSAS1 and BLSAS2 and the monitoring circuit sets MONCS1 and MONCS2 which are disposed under the sub memory cell array SMCA1 of FIG. 2A are illustrated in FIG. 8.

Each of the bitline sense amplifier sets BLSAS1 and BLSAS2 may drive memory cells included in the sub memory cell array SMCA1, the monitoring circuit set MONCS1 may monitor the driving signal set DRVSS1 provided to the bitline sense amplifier set BLSAS1 and may output the monitoring data MDAT1, and the monitoring circuit set MONCS2 may monitor the driving signal set DRVSS2 provided to the bitline sense amplifier set BLSAS2 and may output the monitoring data MDAT2.

The bitline sense amplifier set BLSAS1 and the monitoring circuit set MONCS1 may be configured as described with reference to FIG. 3, and configurations of the bitline sense amplifier set BLSAS2 and the monitoring circuit set MONCS2 may be the same as or similar to the configurations of the bitline sense amplifier set BLSAS1 and the monitoring circuit set MONCS1.

In an embodiment, the bitline sense amplifier set BLSAS1 and the monitoring circuit set MONCS1 may be disposed in the areas of the second semiconductor structure SEMS2 described with reference to FIG. 1. For example, the bitline sense amplifier set BLSAS1 may be disposed in a first area of the second semiconductor structure SEMS2, and the monitoring circuit set MONCS1 may be disposed in a second area of the second semiconductor structure SEMS2.

In an embodiment, as shown in FIG. 3, the bitline sense amplifier set BLSAS1 may include bitline sense amplifiers disposed along the first horizontal direction HD1 at the first column in the first area, and the monitoring circuit set MONCS1 may include monitoring circuits respectively corresponding to the bitline sense amplifiers and disposed along the first horizontal direction HD1 at the second column in the second area, which is parallel to the first column. The bitline sense amplifier set BLSAS1 may be spaced apart from the monitoring circuit set MONCS1 in the second horizontal direction HD2.

In an embodiment, a distance between the corresponding one of the bitline sense amplifiers included in the bitline sense amplifier set BLSAS1 and the corresponding one of the monitoring circuits included in the monitoring circuit set MONCS1 may be identically maintained. For example, a distance between one bitline sense amplifier and one monitoring circuit, which correspond to each other, may be uniform to guarantee the performance of monitoring above a given level. The one bitline sense amplifier and the one monitoring circuit which are arranged in the second horizontal direction HD2 may be connected to the same driving signal. As shown in FIGS. 3 and 8, a distance, in the second horizontal direction HD2, between a bitline sense amplifier BLSA11 and a monitoring circuit MONC11 may be the same as a distance, in the second horizontal direction HD2, between a bitline sense amplifier BLSA12 and a monitoring circuit MONC12. The bitline sense amplifier BLSA11 and the monitoring circuit MONC11 may be arranged in the second horizontal direction HD2, and may be connected to the same driving signals DRVS11. The bitline sense amplifier BLSA12 and the monitoring circuit MONC12 may be arranged in the second horizontal direction HD2, and may be connected to the same driving signals DRVS12. In an embodiment, each of the bitline sense amplifiers may be spaced apart from a corresponding one of the monitoring circuits at substantially the same distance in the second horizontal direction HD2.

FIG. 9 is a block diagram illustrating a semiconductor memory device according to an embodiment of the present disclosure.

Compared to the semiconductor memory device 100 of FIG. 1, a semiconductor memory device 100a of FIG. 9 may further include sub-wordline driver sets (SWDSs) 170a and additional monitoring circuit sets (WMONCSs) 180a. Bitline sense amplifier sets 130a may correspond to the bitline sense amplifier sets 130 of FIG. 1, and monitoring circuit sets (BMONCSs) 140a may correspond to the monitoring circuit sets 140 of FIG. 1. The description given with reference to the embodiment of FIG. 1 will be omitted to avoid redundancy.

The bitline sense amplifier sets 130a may perform the data sensing operation on the plurality of memory cells based on the driving signal sets DRVSSs.

The monitoring circuit sets 140a may monitor the driving signal sets DRVSSs to output a plurality of monitoring data BMDATs.

The sub-wordline driver sets 170a may output driving signal sets WDRVSSs (i.e., wordline driving signal sets) which are provided to a plurality of memory cells (or wordlines).

The monitoring circuit sets 180a may monitor the driving signal sets WDRVSSs to output a plurality of monitoring data WMDATs. The monitoring circuit sets 180a may be the additional monitoring circuit sets described with reference to FIG. 1.

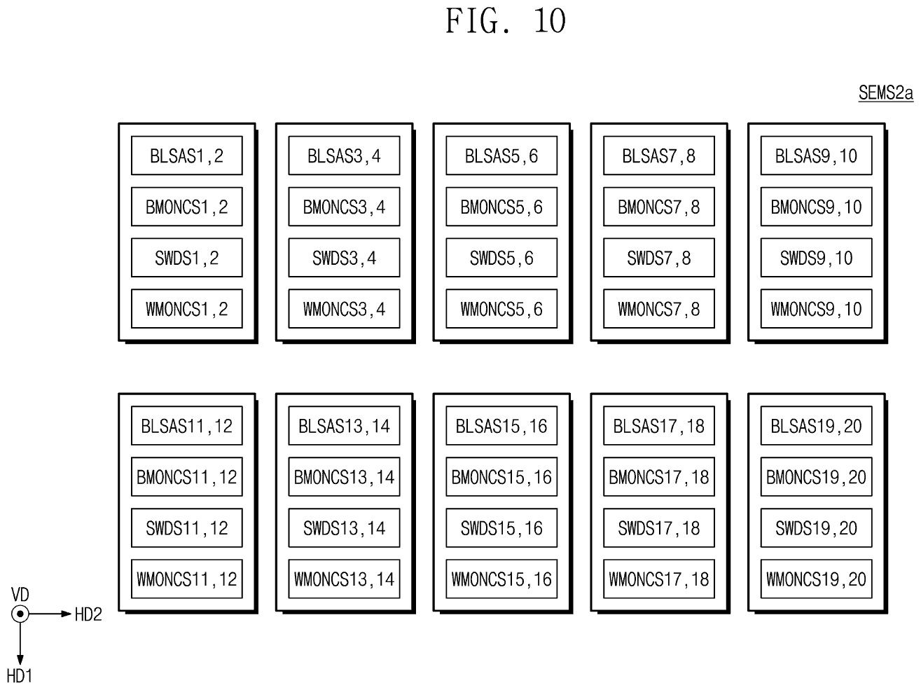

FIG. 10 is a diagram for describing a second semiconductor structure of FIG. 9.

Referring to FIG. 10, a second semiconductor structure SEMS2a may correspond to the second semiconductor structure SEMS2 of FIG. 2B. Compared to the second semiconductor structure SEMS2, the second semiconductor structure SEMS2a may further include sub-wordline driver sets SWDS1, SWDS2, SWDS3, SWDS4, SWDS5, SWDS6, SWDS7, SWDS8, SWDS9, SWDS10, SWDS11, SWDS12, SWDS13, SWDS14, SWDS15, SWDS16, SWDS17, SWDS18, SWDS19, and SWDS20, and monitoring circuit sets WMONCS1, WMONCS2, WMONCS3, WMONCS4, WMONCS5, WMONCS6, WMONCS7, WMONCS8, WMONCS9, WMONCS10, WMONCS11, WMONCS12, WMONCS13, WMONCS14, WMONCS15, WMONCS16, WMONCS17, WMONCS18, WMONCS19, and WMONCS20. The monitoring circuit sets BMONCS1, BMONCS2, BMONCS3, BMONCS4, BMONCS5, BMONCS6, BMONCS7, BMONCS8, BMONCS9, BMONCS10, BMONCS11, BMONCS12, BMONCS13, BMONCS14, BMONCS15, BMONCS16, BMONCS17, BMONCS18, BMONCS19, and BMONCS20 may respectively correspond to the monitoring circuit sets MONCS1 to MONCS20 of FIG. 2B.

Each of the monitoring circuit sets WMONCS1 to WMONCS20 may include a plurality of monitoring circuits.

In an embodiment, as illustrated in FIG. 10, the bitline sense amplifier sets BLSAS1 to BLSAS20, the monitoring circuit sets BMONCS1 to BMONCS20, the sub-wordline driver sets SWDS1 to SWDS20, and the monitoring circuit sets WMONCS1 to WMONCS20 may be disposed in corresponding areas SMCA1 to SMCA10 which are under the plurality of sub memory cell arrays described with reference to FIG. 2A and are within the second semiconductor structure SEMS2a.

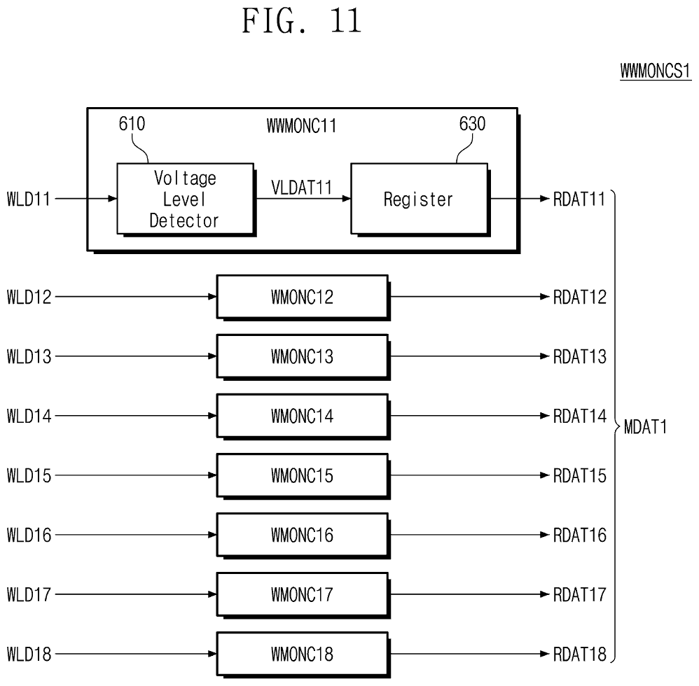

FIG. 11 is a block diagram illustrating an embodiment of a monitoring circuit set of FIG. 10.

Referring to FIG. 11, the monitoring circuit set WMONCS1 may include monitoring circuits WMONC11, WMONC12, WMONC13, WMONC14, WMONC15, WMONC16, WMONC17, and WMONC18. Each of the monitoring circuits WMONC11 to WMONC20 may monitor the voltage level of a driving signal which is provided to one wordline. For example, one monitoring circuit WMONC11 may monitor a driving signal (e.g., WLD11) which is provided to one wordline.

The monitoring circuit WMONC11 may include a voltage level detector 610 and a register 630.

The voltage level detector 610 may monitor the voltage level of the driving signal WLD11 provided to one wordline and may output voltage level data VLDAT11. In an embodiment, the voltage level detector 610 may include a comparator which compares an input voltage with a reference voltage and outputs a high or low signal depending on which is greater.

The register 630 may store the voltage level data VLDAT11 and may output the result data RDAT11.

A configuration and an operation of each of the monitoring circuits WMONC12 to WMONC18 may be the same as or similar to the configuration and the operation of the monitoring circuit WMONC11. Accordingly, the monitoring circuits WMONC12 to WMONC18 may respectively monitor the voltage levels of driving signals WLD12, WLD13, WLD14, WLD15, WLD16, WLD17, and WLD18 and may respectively output the result data RDAT11 to RDAT18.

The result data RDAT11 to RDAT18 may constitute the monitoring data MDAT1.

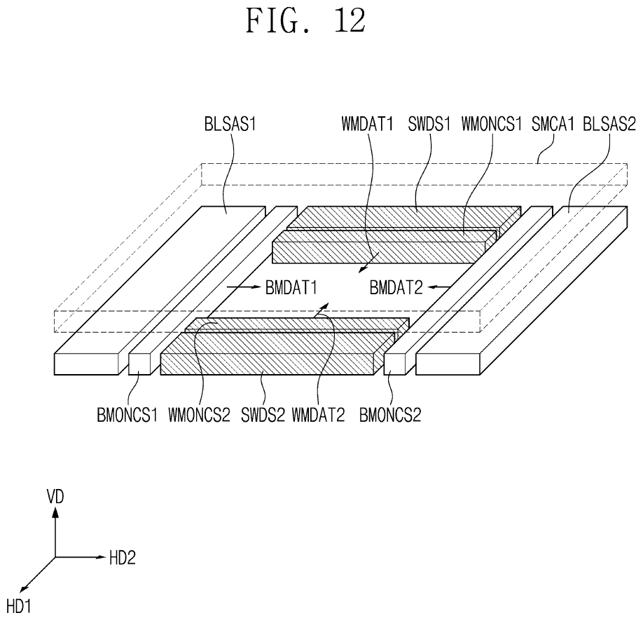

FIG. 12 is a diagram for describing an embodiment of the relation of arrangement of a bitline sense amplifier set, a sub-wordline driver set, and a monitoring circuit set of FIG. 11.

The bitline sense amplifier sets BLSAS1 and BLSAS2, the monitoring circuit sets BMONCS1 and BMONCS2, the sub-wordline driver sets SWDS1 and SWDS2, and the monitoring circuit sets WMONCS1 and WMONCS2 which are disposed under the sub memory cell array SMCA1 of FIG. 2A are illustrated in FIG. 12. Compared to the relation of arrangement of FIG. 8, the relation of arrangement of FIG. 12 may further include the sub-wordline driver sets SWDS1 and SWDS2 and the monitoring circuit sets WMONCS1 and WMONCS2. The description given with reference to the embodiment of FIG. 8 will be omitted to avoid redundancy.

The monitoring circuit set WMONCS1 may be configured as described with reference to FIGS. 9, 10, and 11, and a configuration of the monitoring circuit set WMONCS2 may be the same as or similar to that of the monitoring circuit set WMONCS1.

In an embodiment, the bitline sense amplifier set BLSAS1, the monitoring circuit set BMONCS1, the sub-wordline driver set SWDS1, and the monitoring circuit set WMONCS1 may be disposed in the areas of the second semiconductor structure SEMS2a of FIG. 9. For example, the bitline sense amplifier BLSAS1 may be disposed in a first area of the second semiconductor structure SEMS2a, and the monitoring circuit set MOCNS1 may be disposed in a second area of the second semiconductor structure SEMS2a. The sub-wordline driver set SWDS1 may be disposed in a third area of the second semiconductor structure SEMS2a, and the monitoring circuit set WMONCS1 may be disposed in a fourth area of the second semiconductor structure SEMS2a.

In an embodiment, the bitline sense amplifier set BLSAS1 may include bitline sense amplifiers which are disposed along the first horizontal direction HD1 at the first column in the first area. The monitoring circuit set BMONCS1 may include monitoring circuits which respectively correspond to the bitline sense amplifiers and are disposed along the first horizontal direction HD1 at the second column in the second area, which is parallel to the first column.

In an embodiment, the sub-wordline driver set SWDS1 may include sub-wordline drivers disposed along the second horizontal direction HD2 at the third column in the third area, and the monitoring circuit set WMONCS1 may include monitoring circuits which respectively correspond to the sub-wordline drivers and are disposed along the second horizontal direction HD2 at the fourth column in the fourth area, which is parallel to the third column.

In an embodiment, a distance between the corresponding one of the sub-wordline drivers included in the sub-word line driver set SWDS1 and the corresponding one of the monitoring circuits included in the monitoring circuit set WMONCS1 may be identically maintained. For example, a distance between one sub-word line driver and one monitoring circuit, which correspond to each other, may be uniform to guarantee the performance of monitoring above a given level.

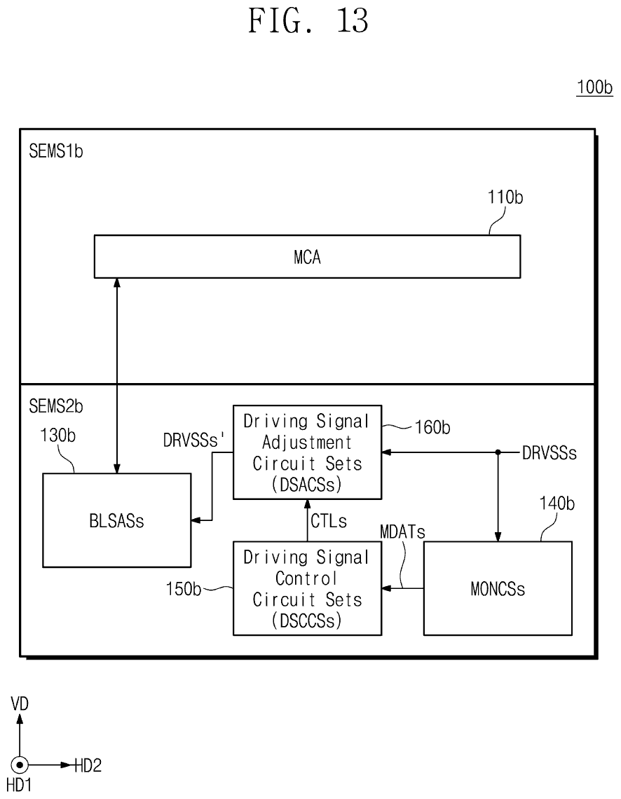

FIG. 13 is a block diagram illustrating a semiconductor memory device according to an embodiment of the present disclosure.

Compared to the semiconductor memory device 100 of FIG. 1, a semiconductor memory device 100b of FIG. 13 may further include driving signal control circuit sets (DSCCs) 150b and driving signal adjustment circuit sets (DSACSs) 160b. Bitline sense amplifier sets 130b may correspond to the bitline sense amplifier sets 130 of FIG. 1, and monitoring circuit sets 140b may correspond to the monitoring circuit sets 140 of FIG. 1. The description given with reference to the embodiment of FIG. 1 will be omitted to avoid redundancy.

The monitoring circuit sets 140b may monitor the driving signal sets DRVSSs to output the plurality of monitoring data MDATs.

The driving signal control circuit sets 150b may generate control signals CTLs based on the monitoring data MDATs.

The driving signal adjustment circuit sets 160b may receive the driving signal set DRVSS including a plurality of driving signals, may adjust driving timings or driving voltage levels of one or more of the driving signals based on the control signals CTLs, and may output adjusted driving signal sets DRVSSs'.

The bitline sense amplifier sets 130b may perform the data sensing operation on the plurality of memory cells based on the adjusted driving signal sets DRVSSs'.

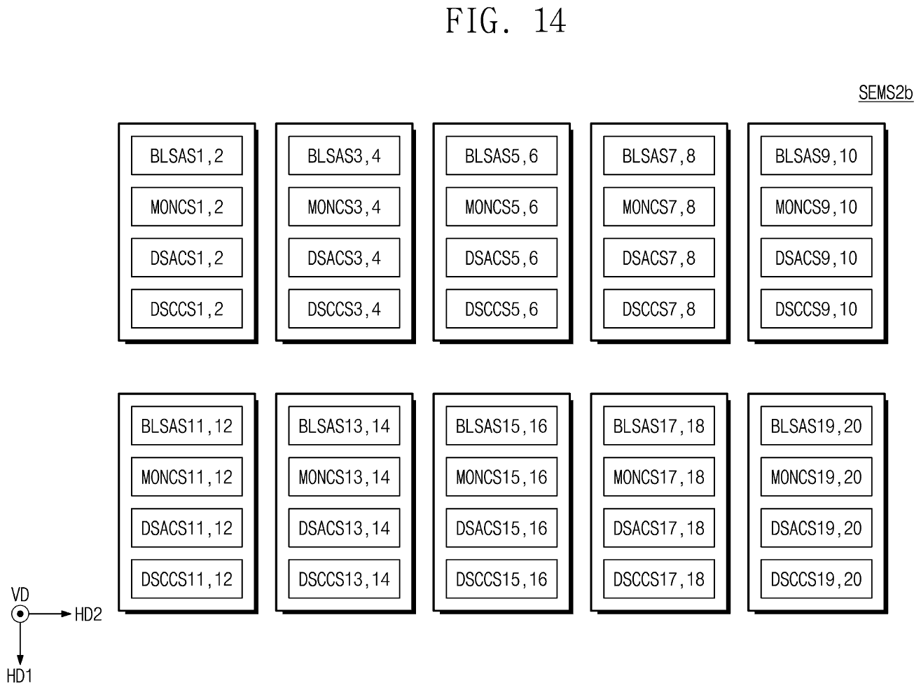

FIG. 14 is a diagram for describing a second semiconductor structure of FIG. 13.

Referring to FIG. 14, a second semiconductor structure SEMS2b may correspond to the second semiconductor structure SEMS2 of FIG. 2B. Compared to the second semiconductor structure SEMS2, the second semiconductor structure SEMS2b may further include driving signal adjustment circuit sets DSACS1, DSACS2, DSACS3, DSACS4, DSACS5, DSACS6, DSACS7, DSACS8, DSACS9, DSACS10, DSACS11, DSACS12, DSACS13, DSACS14, DSACS15, DSACS16, DSACS17, DSACS18, DSACS19, and DSACS20 and driving signal control circuit sets DSCCS1, DSCCS2, DSCCS3, DSCCS4, DSCCS5, DSCCS6, DSCCS7, DSCCS8, DSCCS9, DSCCS10, DSCCS11, DSCCS12, DSCCS13, DSCCS14, DSCCS15, DSCCS16, DSCCS17, DSCCS18, DSCCS19, and DSCCS20.

Each of the driving signal control circuit sets DSCCS1 to DSCCS20 may include a plurality of driving signal control circuits, and each of the driving signal adjustment circuit sets DSACS1 to DSACS20 may include a plurality of driving signal adjustment circuits.

In an embodiment, as illustrated in FIG. 14, the bitline sense amplifier sets BLSAS1 to BLSAS20, the monitoring circuit sets MONCS1 to MONCS20, the driving signal control circuit sets DSCCS1 to DSCCS20, and the driving signal adjustment circuit sets DSACS1 to DSACS20 may be disposed in corresponding areas which are under the plurality of sub memory cell arrays SMCA1 to SMCA10 described with reference to FIG. 2A and are within the second semiconductor structure SEMS2b.

FIG. 15 is a block diagram illustrating an embodiment of a bitline sense amplifier set, a monitoring circuit set, a driving signal adjustment circuit set, and a driving signal control circuit set of FIG. 14.

As described with reference to FIG. 14, the bitline sense amplifier set BLSAS1, the monitoring circuit set MONCS1, the driving signal control circuit set DSCCS1, and the driving signal adjustment circuit set DSACS1 may be disposed in areas which are under the sub memory cell array SMCA1 and are within the second semiconductor structure SEMS2b, together with the bitline sense amplifier set BLSAS2, the monitoring circuit set MONCS2, the driving signal control circuit set DSCCS2, and the driving signal adjustment circuit set DSACS2. For convenience of description, the bitline sense amplifier set BLSAS1, the monitoring circuit set MONCS1, the driving signal control circuit set DSCCS1, and the driving signal adjustment circuit set DSACS1 are only illustrated in FIG. 15. The description given with reference to the embodiment of FIG. 3 will be omitted to avoid redundancy.

Referring to FIG. 15, the driving signal control circuit set DSCCS1 may include driving signal control circuits (not illustrated), and the driving signal adjustment circuit set DSACS1 may include driving signal adjustment circuits DSAC11, DSAC12, DSAC13, DSAC14, DSAC15, DSAC16, DSAC17, and DSAC18.

In an embodiment, the driving signal adjustment circuit DSAC11 may adjust driving timings or driving voltage levels of one or more of the driving signals DRVS11 and may output adjusted driving signals DRVS11′. Operations of the driving signal adjustment circuits DSAC12 to DSAC18 may be similar to the operation of the driving signal adjustment circuit DSAC11, each of the driving signal adjustment circuits DSAC12 to DSAC18 may adjust driving timings or driving voltage levels of one or more of each of the driving signals DRVS12, DRVS13, DRVS14, DRVS15, DRVS16, DRVS17, and DRVS18, and the driving signal adjustment circuits DSAC12 to DSAC18 may respectively output adjusted driving signals DRVS12′, DRVS13′, DRVS14′, DRVS15′, DRVS16′, DRVS17′, and DRVS18′.

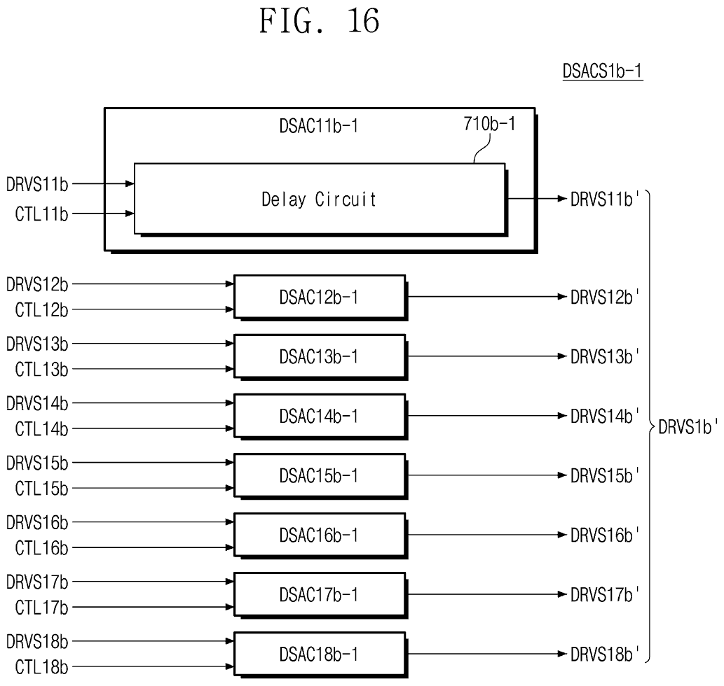

FIG. 16 is a block diagram illustrating an embodiment of a driving signal adjustment circuit set of FIG. 15.

Referring to FIG. 16, a driving signal adjustment circuit set DSACS1b-1 may include driving signal adjustment circuits DSAC11b-1, DSAC12b-1, DSAC13b-1, DSAC14b-1, DSAC15b-1, DSAC16b-1, DSAC17b-1, and DSAC18b-1. Each of the driving signal adjustment circuits DSAC11b-1 to DSAC18b-1 may adjust driving timings of one or more of driving signals provided to one bitline sense amplifier and may output adjusted driving signals. The driving signal adjustment circuit set DSACS1b-1 may correspond to one of the driving signal adjustment circuits DSAC11, DSAC12, DSAC13, DSAC14, DSAC15, DSAC16, DSAC17, and DSAC18.

The driving signal adjustment circuit DSAC11b-1 may include a delay circuit 710b-1. The delay circuit 710b-1 may generate adjusted driving signals DRVS11b′ based on one or more of the driving signals DRVS11b and a control signal CTL11b.

In an embodiment, the delay circuit 710b-1 may generate the adjusted driving signals DRVS11b′ by delaying one or more of the driving signals DRVS11b as much as a preset time based on the control signal CTL11b.

A configuration and an operation of each of the driving signal adjustment circuits DSAC12b-1 to DSAC18b-1 may be the same as or similar to the configuration and the operation of the driving signal adjustment circuit DSAC11b-1. Accordingly, each of the driving signal adjustment circuits DSAC12b-1 to DSAC18b-1 may delay one or more of each of the driving signals DRVS12, DRVS13, DRVS14, DRVS15, DRVS16, DRVS17, and DRVS18 as much as a given time, and the driving signal adjustment circuits DSAC12b-1 to DSAC18b-1 may generate adjusted driving signals DRVS12b′, DRVS13b′, DRVS14b′, DRVS15b′, DRVS16b′, DRVS17b′, and DRVS18b′. The adjusted driving signals DRVS11b′ to DRVS18b′ may constitute an adjusted driving signal set DRVS1b′.

In an embodiment, delay amounts of one or more of corresponding driving signals delayed by each of the driving signal adjustment circuits DSAC12b-1 to DSAC18b-1 may be different from each other.

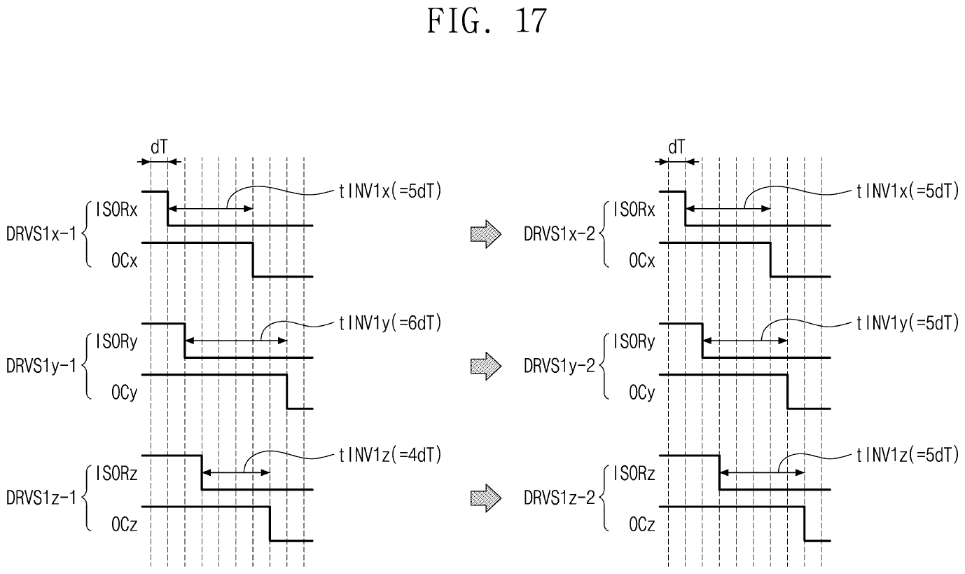

FIG. 17 is a diagram for describing an operation of a driving signal adjustment circuit set of FIG. 16.

Referring to FIG. 17, driving signals DRVS1x-1, DRVS1y-1, and DRVS1z-1 and adjusted driving signals DRVS1x-2, DRVS1y-2, and DRVS1z-2 are illustrated, each of the driving signals DRVS1x-1, DRVS1y-1, and DRVS1z-1 may be one of the driving signals DRVS11b to DRVS18b of FIG. 16, and each of the adjusted driving signals DRVS1x-2, DRVS1y-2, and DRVS1z-2 may be one of the adjusted driving signals DRVS11b′ to DRVS18b′ of FIG. 16.

In an embodiment, in each of the driving signals DRVS1x-1, DRVS1y-1, and DRVS1z-1, a time interval between transition time points of a first driving signal and a second driving signal may be monitored. For example, a time interval targeted for the monitoring may be the time interval tINV1 described with reference to FIG. 4B, the first driving signal may be an isolation release signal (e.g., ISORx, ISORy, or ISORz), and the second driving signal may be an offset compensation signal (e.g., OCx, OCy, or OCz). For example, according to the embodiments described with reference to FIGS. 6 to 8, a time interval (e.g., a time interval where the “offset compensation operation” is performed) from a time point when the first driving signal transitions from the high level to the low level to a time point when the second driving signal transitions from the high level to the low level may be monitored.

For example, a result of performing the monitoring for the driving signal DRVS1x-1 may indicate that a monitored time interval tINV1x is 5dT (herein, dT being a unit time interval), a result of performing the monitoring for the driving signal DRVS1y-1 may indicate that a monitored time interval tINV1y is 6dT, and a result of performing the monitoring for the driving signal DRVS1z-1 may indicate that a monitored time interval tINV1z is 4dT. In an embodiment, the event time-interval detector 510-1 may include a time interval counter generating a plurality of pulses as an output to represent a time interval between two signals, the unit time interval of dT may correspond to a pulse period.

For example, each of the driving signals DRVS1x-1, DRVS1y-1, and DRVS1z-1 may be adjusted by one of the driving signal adjustment circuits DSAC11b-1 to DSAC18b-1 of FIG. 16, and adjusted driving signals DRVS1x-2, DRVS1y-2, and DRVS1z-2 may be obtained by adjusting the driving signals DRVS1x-1, DRVS1y-1, and DRVS1z-1 such that each of the adjusted driving signals DRVS1x-2, DRVS1y-2, and DRVS1z-2 has the same time interval (e.g., 5dT). The time interval tINV1 described with reference to FIG. 4B may be identically set (or defined) in respective bitline sense amplifiers by the adjusted driving signals DRVS1x-2, DRVS1y-2, and DRVS1z-2.

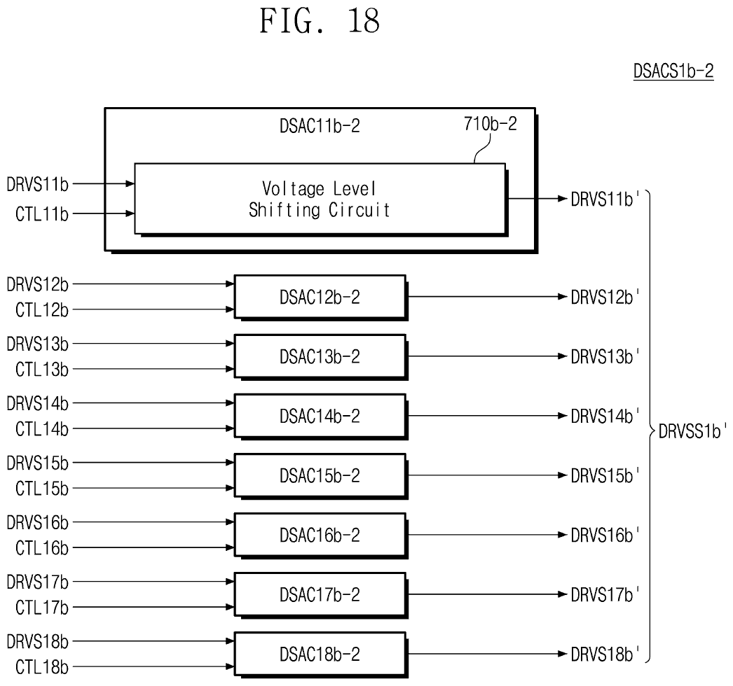

FIG. 18 is a block diagram illustrating an embodiment of a driving signal adjustment circuit set of FIG. 15.

Referring to FIG. 18, a driving signal adjustment circuit set DSACS1b-2 may include driving signal adjustment circuits DSAC11b-2, DSAC12b-2, DSAC13b-2, DSAC14b-2, DSAC15b-2, DSAC16b-2, DSAC17b-2, and DSAC18b-2. Each of the driving signal adjustment circuits DSAC11b-2 to DSAC18b-2 may adjust driving voltage levels of one or more of driving signals provided to one bitline sense amplifier and may output adjusted driving signals. The driving signal adjustment circuit set DSACS1b-2 may correspond to one of the driving signal adjustment circuits DSAC11, DSAC12, DSAC13, DSAC14, DSAC15, DSAC16, DSAC17, and DSAC18.

The driving signal adjustment circuit DSAC11b-2 may include a voltage level shifting circuit 710b-2. The voltage level shifting circuit 710b-2 may generate the adjusted driving signals DRVS11b′ based on one or more of the driving signals DRVS11b and the control signal CTL11b.

In an embodiment, the voltage level shifting circuit 710b-2 may generate the adjusted driving signals DRVS11b′ by increasing or decreasing voltage levels of one or more of the driving signals DRVS11b based on the control signal CTL11b.

A configuration and an operation of each of the driving signal adjustment circuits DSAC12b-2 to DSAC18b-2 may be the same as or similar to the configuration and the operation of the driving signal adjustment circuit DSAC11b-2. Accordingly, each of the driving signal adjustment circuits DSAC12b-2 to DSAC18b-2 may increase or decrease voltage levels of one or more of each of the driving signals DRVS12 to DRVS18, and thus, the driving signal adjustment circuits DSAC12b-2 to DSAC18b-2 may generate the adjusted driving signals DRVS12b′ to DRVS18b′. The adjusted driving signals DRVS12b′ to DRVS18b′ may constitute the adjusted driving signal set DRVS1b′.

In an embodiment, increments or decrements of one or more of corresponding driving signals increased or decreased by each of the driving signal adjustment circuits DSAC12b-2 to DSAC18b-2 may be different from each other.

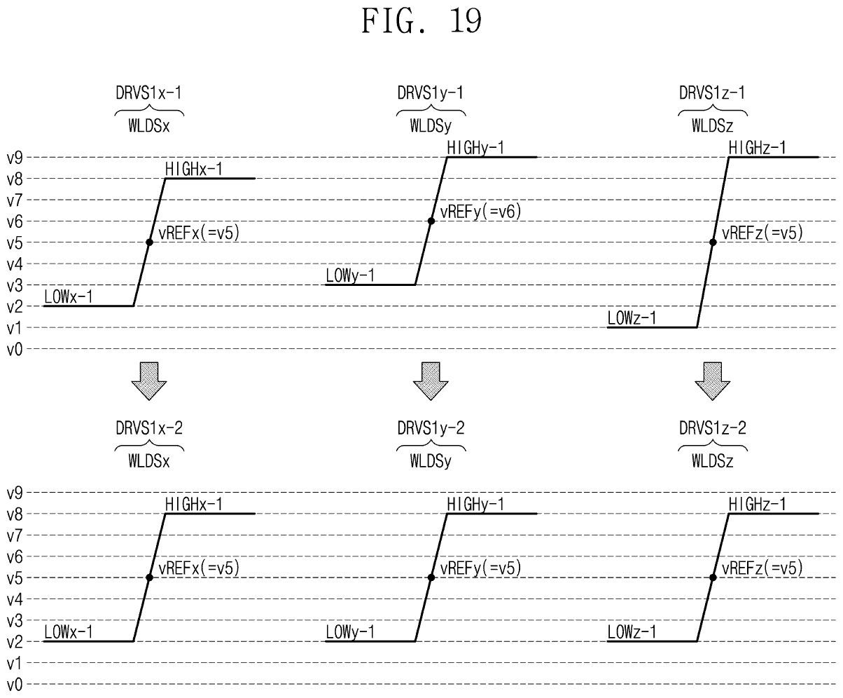

FIG. 19 is a diagram for describing an operation of a driving signal adjustment circuit set of FIG. 18.

Referring to FIG. 19, the driving signals DRVS1x-1, DRVS1y-1, and DRVS1z-1 and the adjusted driving signals DRVS1x-2, DRVS1y-2, and DRVS1z-2 are illustrated, each of the driving signals DRVS1x-1, DRVS1y-1, and DRVS1z-1 may be one of the driving signals DRVS11b to DRVS18b of FIG. 18, and each of the adjusted driving signals DRVS1x-2, DRVS1y-2, and DRVS1z-2 may be one of the adjusted driving signals DRVS11b′ to DRVS12b′ of FIG. 18.

In an embodiment, in each of the driving signals DRVS1x-1, DRVS1y-1, and DRVS1z-1, the voltage level of a third driving signal may be monitored. For example, the voltage level targeted for the monitoring may be the voltage level of the driving signal WLD provided to a wordline, which is described with reference to FIG. 4B. For example, according to the embodiments described with reference to FIGS. 9 to 12, the low level of the third driving signal, the high level of the third driving signal, and an intermediate level between the low level and the high level of the third driving signal may be monitored.

For example, a result of performing the monitoring for the driving signal DRVS1x-1 may indicate that a monitored voltage level WLDSx has a low level LOWx-1, an intermediate level vREFx, and a high level HIGHx-1. A result of performing the monitoring for the driving signal DRVS1y-1 may indicate that a monitored voltage level WLDSy has a low level LOWy-1, an intermediate level vREFy, and a high level HIGHy-1. A result of performing the monitoring for the driving signal DRVS1z-1 may indicate that a monitored voltage level WLDSz has a low level LOWz-1, an intermediate level vREFz, and a high level HIGHz-1.

For example, each of the driving signals DRVS1x-1, DRVS1y-1, and DRVS1z-1 may be adjusted by one of the driving signal adjustment circuits DSAC11b to DSAC18b of FIG. 18, and the adjusted driving signals DRVS1x-2, DRVS1y-2, and DRVS1z-2 may be obtained by adjusting the driving signals DRVS1x-1, DRVS1y-1, and DRVS1z-1 such that the adjusted driving signals DRVS1x-2, DRVS1y-2, and DRVS1z-2 identically have a low level LOWx-2, the intermediate level vREFx, and a high level HIGHx-2. Voltage levels of driving signals which are provided to memory cells (or wordlines) may be identically set (or defined) by the adjusted driving signals DRVS1x-2, DRVS1y-2, and DRVS1z-2, and the time interval (e.g., tINV13) described with reference to FIG. 4B may also be uniformly set (or defined).

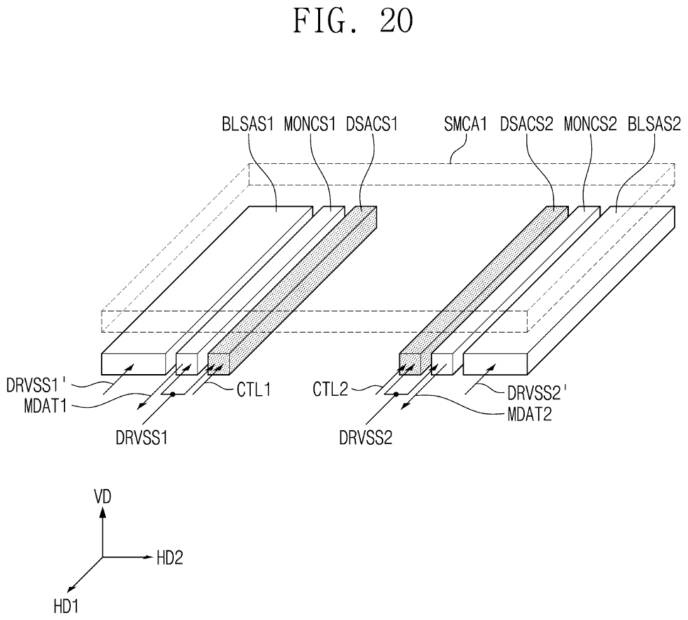

FIG. 20 is a diagram for describing an embodiment of the relation of arrangement of a bitline sense amplifier set, a monitoring circuit set, and a driving signal adjustment circuit set of FIG. 15.

The bitline sense amplifier sets BLSAS1 and BLSAS2, the monitoring circuit sets MONCS1 and MONCS2, and the driving signal adjustment circuit sets DSACS1 and DSACS2 which are disposed under the sub memory cell array SMCA1 of FIG. 2A are illustrated in FIG. 20. Compared to the relation of arrangement of FIG. 8, the relation of arrangement of FIG. 20 may further include the driving signal adjustment circuit sets DSACS1 and DSACS2. The description given with reference to the embodiment of FIG. 8 will be omitted to avoid redundancy.

The bitline sense amplifier set BLSAS1, the monitoring circuit set MONCS1, and the driving signal adjustment circuit set DSACS1 may be configured as described with reference to 15, 16, and FIG. 18, and configurations of the bitline sense amplifier set BLSAS2, the monitoring circuit set MONCS2, and the driving signal adjustment circuit set DSACS2 may be the same as or similar to the configurations of the bitline sense amplifier set BLSAS1, the monitoring circuit set MONCS1, and the driving signal adjustment circuit set DSACS1.

In an embodiment, the bitline sense amplifier set BLSAS1, the monitoring circuit set MONCS1, and the driving signal adjustment circuit set DSACS1 may be disposed in the areas of the second semiconductor structure SEMS2b of FIG. 13. For example, the bitline sense amplifier set BLSAS1 may be disposed in a first area of the second semiconductor structure SEMS2b, the monitoring circuit set MONCS1 may be disposed in a second area of the second semiconductor structure SEMS2b, and the driving signal adjustment circuit set DSACS1 may be disposed in a third area of the second semiconductor structure SEMS2b.

In an embodiment, the bitline sense amplifier set BLSAS1 may include bitline sense amplifiers which are disposed along the first horizontal direction HD1 at the first column in the first area. The monitoring circuit set MONCS1 may include monitoring circuits which respectively correspond to the bitline sense amplifiers and are disposed along the first horizontal direction HD1 at the second column in the second area, which is parallel to the first column. The driving signal adjustment circuit set DSACS1 may include driving signal adjustment circuits which respectively correspond to the bitline sense amplifiers or the monitoring circuits and are disposed along the first horizontal direction HD1 at the third column in the third area, which is parallel to the first column or the second column.

In an embodiment, a distance between the corresponding one of the monitoring circuits included in the monitoring circuit set MONCS1 and the corresponding one of the driving signal adjustment circuits included in the driving signal adjustment circuit set DSACS1 may be identically maintained. For example, a distance between one monitoring circuit and one driving signal adjustment circuit, which correspond to each other, may be uniform to guarantee the performance of adjusting a driving signal above a given level.

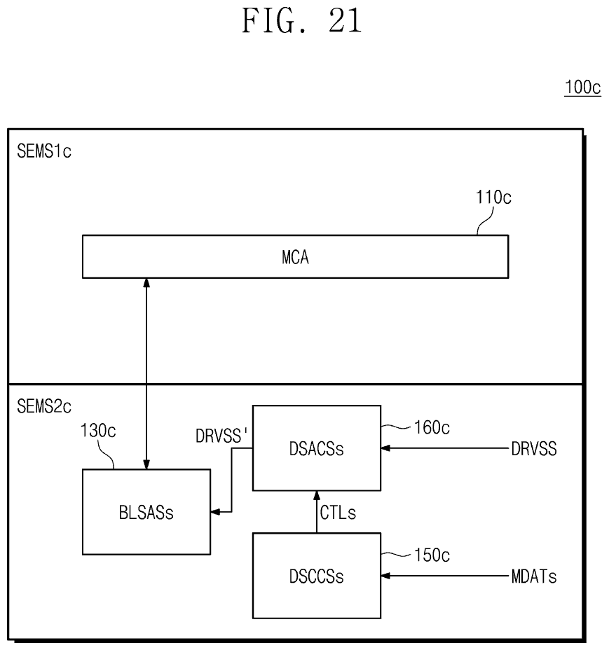

FIG. 21 is a block diagram illustrating a semiconductor memory device according to an embodiment of the present disclosure.

Compared to the semiconductor memory device 100b of FIG. 13, a semiconductor memory device 100c of FIG. 21 may not include monitoring circuit sets (e.g., 140b of FIG. 13). Bitline sense amplifier sets 130c, driving signal control circuit sets 150c, and driving signal adjustment circuit sets 160c may respectively correspond to the bitline sense amplifier sets 130b, the driving signal control circuit sets 150b, and the driving signal adjustment circuit sets 160b of FIG. 13. The description given with reference to the embodiment of FIG. 13 will be omitted to avoid redundancy.

The driving signal control circuit sets 150c may generate the control signals CTLs based on the monitoring data MDATs. However, compared to the semiconductor memory device 100b of FIG. 13, the semiconductor memory device 100c of FIG. 21 may not include the monitoring circuit sets, and the monitoring data MDATs may be generated from monitoring circuit sets of an external semiconductor memory device different from the semiconductor memory device 100c and may then be input to the semiconductor memory device 100c. For example, the monitoring data MDATs may be received from the external semiconductor memory device and may be applied to the semiconductor memory device 100c.

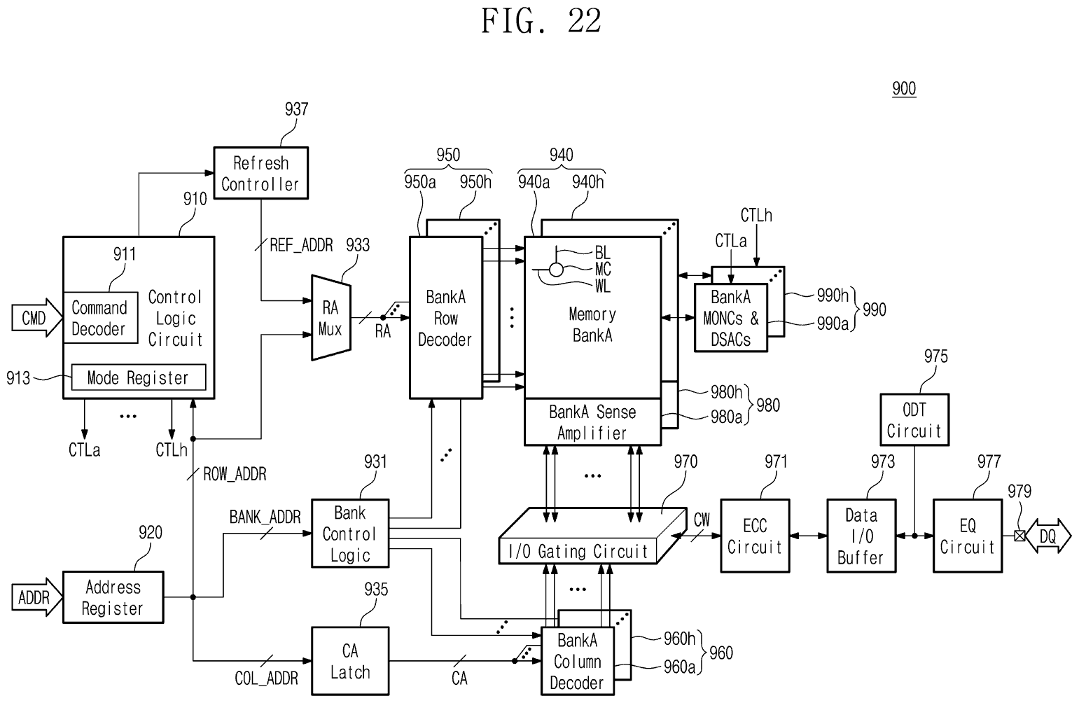

FIG. 22 is a block diagram illustrating a semiconductor memory device according to an embodiment of the present disclosure.

Referring to FIG. 22, a memory device 900 may include a control logic circuit 910, an address register 920, bank control logic 931, a row address multiplexer 933, a column address latch 935, a refresh controller 937, a bank array 940, a row decoder 950, a column decoder 960, an input/output (I/O) gating circuit 970, an error correction code (ECC) circuit 971, a data input/output (I/O) buffer 973, an on-die termination (ODT) circuit 975, an equalizer circuit 977, a data input/output pad 979, bitline sense amplifier sets 980, and monitoring circuits and driving signal adjustment circuits (MONCs & DSACs) 990. The control logic circuit 910 may include a command decoder 911 and a mode register 913. For example, the memory device 900 may be a volatile memory device. In particular, the memory device 900 may be a dynamic random access memory (DRAM).

The bank array 940 may include a plurality bank arrays 940a and 940h. The row decoder 950 may include a plurality of bank row decoders 950a and 950h respectively connected to the plurality of bank arrays 940a and 940h, the column decoder 960 may include a plurality of bank column decoders 960a and 960h respectively connected to the plurality of bank arrays 940a and 940h, and the bitline sense amplifier sets 980 may include a plurality of bank sense amplifiers 980a and 980h respectively connected to the plurality of bank arrays 940a and 940h. The plurality of bank arrays 940a and 940h, the plurality of bank row decoders 950a and 950h, and the plurality of bank column decoders 960a and 960h may constitute a plurality of banks. Each of the plurality of bank arrays 940a and 940h may include a plurality of memory cells MC which are formed at intersections of a plurality of wordlines WLs and a plurality of bitlines BLs.

The address register 920 may receive an address ADDR including a bank address BANK_ADDR, a row address ROW_ADDR, and a column address COL_ADDR from a memory controller. The address register 920 may provide the bank address BANK_ADDR to the bank control logic 931, may provide the row address ROW_ADDR to the row decoder 950 through the row address multiplexer 933, and may provide the column address COL_ADDR to the column decoder 960 through the column address latch 935.

The bank control logic 931 may generate bank control signals in response to the bank address BANK_ADDR. The bank row decoders 950a and 950h and the bank column decoders 960a and 960h corresponding the bank address BANK_ADDR may be activated based on the bank control signals.

The refresh controller 937 may generate a refresh row address REF_ADDR which sequentially increases or decreases under control of the control logic circuit 910.

Activated bank column decoders among the plurality of bank column decoders 960a and 960h may activate the bank sense amplifiers 980a and 980h corresponding to the bank address BANK_ADDR, the row address ROW_ADDR, and the column address COL_ADDR by using the input/output gating circuit 970.

A codeword CW read from one of the plurality of bank arrays 940a and 940h may be sensed by a bank sense amplifier corresponding to the one bank array, the ECC circuit 971 may perform ECC decoding for the sensed codeword CW, and the codeword CW experiencing the ECC decoding may be provided to the memory controller through the data input/output buffer 973 as a DQ signal.

Data to be written in one of the plurality of bank arrays 940a and 940h may be provided to the ECC circuit 971, the ECC circuit 971 may generate parity bits based on the provided data and may provide a codeword including the provided data and the parity bits to the input/output gating circuit 970, and the input/output gating circuit 970 may write the codeword in the one bank array.

The ODT circuit 975 may be connected to the data input/output pad 979 and the data input/output buffer 973 and may perform impedance matching.

The control logic circuit 910 may control an operation of the memory device 900. For example, the control logic circuit 910 may generate control signals such that the memory device 900 performs the write operation or the read operation. The command decoder 911 may decode a command CMD received from the memory controller, and the mode register 913 may set an operation mode of the memory device 900. For example, the command decoder 911 may decode a write enable signal, a row address strobe signal, a column address strobe signal, a chip select signal, etc. and may generate the control signals corresponding to the command CMD.

The monitoring circuits and driving signal adjustment circuits (MONCs & DSACs) 990 may respectively correspond to the plurality of bank arrays 940a and 940h and may include the plurality of monitoring circuits described with reference to FIGS. 1, 3, and 6 and the driving signal adjustment circuits described with reference to FIGS. 16 and 18. Accordingly, the monitoring circuits and driving signal adjustment circuits 990 may monitor driving signal sets to output monitoring data, and the monitoring circuits and driving signal adjustment circuits 990 may adjust driving timings or driving voltage levels of one or more of the driving signal sets and may output adjusted driving signals.

The control logic circuit 910 may further generate control signals CTLa and CTLh. For example, the control logic circuit 910 may include the driving signal control circuits described with reference to FIG. 13 and may generate the control signals CTLa and CTLh based on the monitoring data. For example, the control signals CTLa and CTLh may include the control signals CTLs described with reference to FIG. 13.

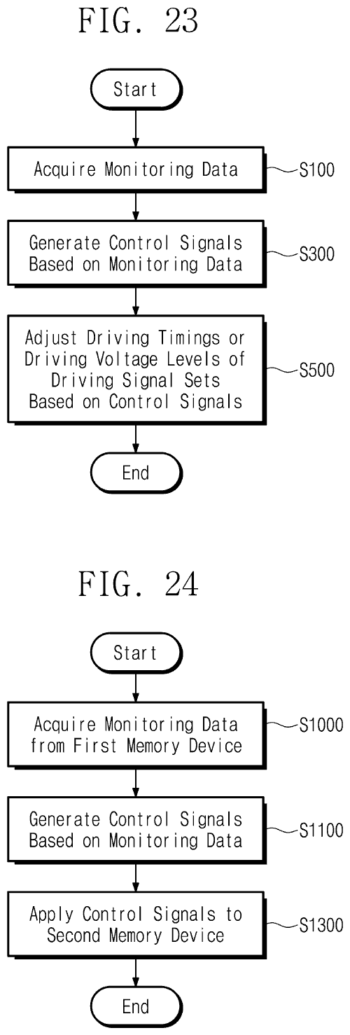

FIG. 23 is a flowchart illustrating an operating method of a semiconductor memory device according to an embodiment of the present disclosure.

Referring to FIG. 23, a plurality of monitoring data may be acquired (S100).

In an embodiment, the plurality of monitoring data may be acquired by monitoring circuit sets including monitoring circuits in a specific semiconductor memory device. For example, the plurality of monitoring data may be acquired by the monitoring circuit sets 140, 140a, 140b, and 180a described with reference to FIGS. 1, 9, and 13.

Control signals may be generated based on the plurality of monitoring data (S300).

Driving timings or driving voltage levels of driving signal sets may be adjusted based on the control signals (S500).

In an embodiment, the adjusted driving signal sets may be provided to bitline sense amplifier sets including a plurality of bitline sense amplifiers or may be provided to a memory cell array including a plurality of memory cells.

FIG. 24 is a flowchart illustrating an operating method of a semiconductor memory device according to an embodiment of the present disclosure.

Referring to FIG. 24, a plurality of monitoring data may be acquired from a first memory device (S1000). The first memory device may include monitoring circuit sets which perform monitoring operations as described with reference to FIGS. 1, 9, and 13 to generate the plurality of monitoring data. The monitoring circuit sets of the first memory device may correspond to the monitoring circuit sets 140, 140a, 140b, and 180a described with reference to FIGS. 1, 9, and 13.

Control signals may be generated based on the plurality of monitoring data (S1100).

The control signals may be applied to a second memory device (S1300).

In an embodiment, the second memory device may be the semiconductor memory device 100c described with reference to FIG. 21. The second memory device may be a memory device manufactured through the same semiconductor manufacturing process as the first memory device.

As described above, a semiconductor memory device according to embodiments of the present disclosure may monitor driving signals provided to a plurality of bitline sense amplifiers or a plurality of memory cells and may adjust driving timings or driving voltage levels of the driving signals based on a result of the monitoring. The monitoring may be directly associated with main features affecting the performance of bitline sense amplifiers or the like. Accordingly, the semiconductor memory device may optimize elements capable of affecting the yield of the semiconductor memory device depending on the adjusting of the driving timings or the driving voltage levels or the monitoring, and thus, the performance of the semiconductor memory device may be improved.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A semiconductor memory device comprising:
a first semiconductor structure including a memory cell array including a plurality of memory cells; and
a second semiconductor structure vertically stacked on the first semiconductor structure, the second semiconductor structure including:
a plurality of bitline sense amplifier sets configured to perform a data sensing operation on the plurality of memory cells based on a plurality of driving signal sets; and
a plurality of monitoring circuit sets configured to monitor the plurality of driving signal sets and output a plurality of monitoring data.

2. The semiconductor memory device of claim 1,
wherein each driving signal set of the plurality of driving signal sets includes a plurality of first driving signals,
wherein each bitline sense amplifier set of the plurality of bitline sense amplifier sets includes a first bitline sense amplifier configured to perform the data sensing operation based on the plurality of first driving signals, and
wherein each monitoring circuit set of the plurality of monitoring circuit sets includes a first monitoring circuit configured to monitor one or more of the plurality of first driving signals.

3. The semiconductor memory device of claim 2,
wherein the first bitline sense amplifier includes a plurality of metal oxide semiconductor (MOS) transistors configured to perform the data sensing operation, and
wherein the plurality of first driving signals includes a plurality of gate signals of the plurality of MOS transistors.

4. The semiconductor memory device of claim 3,
wherein the plurality of first driving signals includes a first gate signal and a second gate signal, and
wherein the first monitoring circuit is configured to monitor a time interval between a transition time point of a voltage level of the first gate signal and a transition time point of a voltage level of the second gate signal.

5. The semiconductor memory device of claim 4,
wherein the first bitline sense amplifier includes:
a first isolation transistor connected between a first bitline and a first sensing node;
a first offset compensation transistor connected between the first bitline and a second sensing node; and
an equalization transistor configured to selectively connect the first sensing node to the second sensing node, and
wherein the first gate signal is a gate signal of the first isolation transistor, and the second gate signal is a gate signal of the first offset compensation transistor.

6. The semiconductor memory device of claim 5,
wherein the first monitoring circuit is configured to monitor a time interval between a time point when the voltage level of the first gate signal transitions from a first logic level to a second logic level and a time point when the voltage level of the second gate signal transitions from the first logic level to the second logic level.

7. The semiconductor memory device of claim 6,
wherein the data sensing operation includes an offset compensation operation, and
wherein the first monitoring circuit is configured to monitor a time interval in which the first bitline sense amplifier performs the offset compensation operation.

8. The semiconductor memory device of claim 4,
wherein the first bitline sense amplifier includes:
a first isolation transistor connected between a first bitline and a first sensing node; and
a first power supply transistor connected between a power node and a power supply node, and
wherein the first gate signal is a gate signal of the first isolation transistor, and the second gate signal is a gate signal of the first power supply transistor.

9. The semiconductor memory device of claim 8,
wherein the data sensing operation includes a charge sharing operation in a charge sharing time interval,
wherein the first monitoring circuit is configured to monitor a portion of the charge sharing time interval,
wherein the portion of the charge sharing time interval corresponds to a time interval between a time point when the first gate signal transitions from a high level to a low level and a time point when a pre-sensing operation starts, and
wherein the starting of the pre-sensing operation includes the second gate signal transitioning from a low level to a high level.

10. The semiconductor memory device of claim 3,
wherein the plurality of first driving signals includes a first gate signal applied to a gate electrode of one of the plurality of MOS transistors, and
wherein the first monitoring circuit is configured to monitor a transition time point of a voltage level of the first gate signal.

11. The semiconductor memory device of claim 2,
wherein the second semiconductor structure further includes a plurality of sub-wordline driver sets configured to provide a plurality of wordline driving signals to the plurality of memory cells,
wherein the plurality of wordline driving signals include a first wordline driving signal, and
wherein the first monitoring circuit is configured to monitor a transition time point of a voltage level of the first wordline driving signal.

12. The semiconductor memory device of claim 1, further comprising:
a plurality of driving signal control circuit sets configured to generate a plurality of control signals based on the plurality of monitoring data; and
a plurality of driving signal adjustment circuit sets configured to adjust driving timings or driving voltage levels of the plurality of driving signal sets based on the plurality of control signals.

13. The semiconductor memory device of claim 12,
wherein the plurality of driving signal sets includes:
a plurality of first driving signals associated with driving a first set of bitline sense amplifiers; and
a plurality of second driving signals associated with driving a second set of bitline sense amplifiers different from the first set of bitline sense amplifiers,
wherein the plurality of monitoring circuit sets include:
a first monitoring circuit set configured to monitor the plurality of first driving signals to output first result data, and
a second monitoring circuit set configured to monitor the plurality of second driving signals to output second result data,
wherein the plurality of monitoring data includes the first result data and the second result data, and
wherein the plurality of driving signal adjustment circuit sets include:
a first driving signal adjustment circuit set configured to adjust the plurality of first driving signals to generate a plurality of first adjusted driving signals in response to the first result data, and
a second driving signal adjustment circuit set configured to adjust the plurality of second driving signals to generate a plurality of second adjusted driving signals in response to the second result data.

14. The semiconductor memory device of claim 13,
wherein the first driving signal adjustment circuit set is configured to generate the plurality of first adjusted driving signals by adjusting a driving timing of each of the plurality of first driving signals.

15. A semiconductor memory device with a cell over periphery (COP), the semiconductor memory device comprising:
a first semiconductor structure including a memory cell array including a plurality of memory cells; and
a second semiconductor structure disposed under the first semiconductor structure, the second semiconductor structure including:
a plurality of bitline sense amplifier sets disposed in a first area of the second semiconductor structure, the plurality of bitline sense amplifier sets configured to perform a data sensing operation on the plurality of memory cells based on a plurality of driving signal sets; and
a plurality of monitoring circuit sets disposed in a second area of the second semiconductor structure, the plurality of monitoring circuit sets configured to monitor the plurality of driving signal sets to output a plurality of monitoring data.

16. The semiconductor memory device of claim 15,
wherein each of the plurality of bitline sense amplifier sets includes a plurality of bitline sense amplifiers,
wherein each of the plurality of monitoring circuit sets includes a plurality of monitoring circuits,
wherein each of the plurality of bitline sense amplifiers is configured to perform the data sensing operation based on a corresponding driving signal set among the plurality of driving signal sets, and
wherein each of the plurality of monitoring circuits is configured to monitor a corresponding driving signal set among the driving signal sets.

17. The semiconductor memory device of claim 16,
wherein the plurality bitline sense amplifier sets include a first bitline sense amplifier set having a plurality of first bitline sense amplifiers,
wherein the plurality of monitoring circuit sets includes a first monitoring circuit set having a plurality of first monitoring circuits,
wherein the plurality of driving signal sets includes a first driving signal sets having a plurality of first driving signals,
wherein one of the plurality of first bitline sense amplifiers and one of the plurality of first monitoring circuits are configured to receive a corresponding one of the plurality of first driving signals,
wherein the plurality of first bitline sense amplifiers are disposed at a first column in the first area,
wherein the plurality of first monitoring circuits is disposed at a second column in the second area, which is parallel to the first column, and
wherein the first column and the second column extend in a first horizontal direction and are spaced apart from each other in a second horizontal direction perpendicular to the first horizontal direction.

18. The semiconductor memory device of claim 17,
wherein each of the plurality of first bitline sense amplifiers is spaced apart from a corresponding one of the plurality of first monitoring circuits at substantially the same distance in the second horizontal direction.

19. The semiconductor memory device of claim 17, further comprising:
a plurality of driving signal adjustment circuit sets disposed in the second area, and configured to adjust driving timings or driving voltage levels of the plurality of driving signal sets based on a plurality of control signals,
wherein the plurality of driving signal adjustment circuit sets includes a first driving signal adjustment circuit set having a plurality of first driving signal adjustment circuits respectively corresponding to the plurality of first bitline sense amplifiers, and
wherein the plurality of first driving signal adjustment circuits is disposed at a third column in the second area, which is parallel to the first column.

20. A semiconductor memory device with a periphery over cell (POC), the semiconductor memory device comprising:
a first semiconductor structure including a memory cell array including a plurality of memory cells; and
a second semiconductor structure disposed over the first semiconductor structure,
the second semiconductor structure including:
a plurality of bitline sense amplifier sets configured to perform a data sensing operation on the plurality of memory cells based on a plurality of driving signal sets; and
a plurality of monitoring circuit sets configured to monitor the plurality of driving signal sets and output a plurality of monitoring data.
